(19) United States
(12) Patent Application Publication
(10) Pub. No.: US 2021/0395645 A1
(43) Pub. Date: Dec. 23, 2021

(54) CLEANING LIQUID

(71) Applicant: FUJIFILM Electronic Materials Co., Ltd., Yokohama-shi (JP)

(72) Inventors: Tetsuya Kamimura, Kawagoe-shi (JP); Tsutomu Watahiki, Kawagoe-shi (JP)

(73) Assignee: FUJIFILM Electronic Materials Co., Ltd., Yokohama-shi (JP)

(21) Appl. No.: 17/466,211

(22) Filed: Sep. 3, 2021

Related U.S. Application Data
(63) Continuation of application No. PCT/JP2020/006200, filed on Feb. 18, 2020.

(30) Foreign Application Priority Data
Mar. 26, 2019 (JP) 2019-058577
Jul. 11, 2019 (JP) 2019-129040

(51) Int. Cl. C11D 1/34; C11D 3/33; C11D 3/28; C11D 1/66; H01L 21/02

(52) U.S. Cl. CPC C11D 1/345; C11D 3/33; H01L 21/3212; C11D 1/66; H01L 21/02057; C11D 3/28

(57) ABSTRACT

An object of the present invention is to provide a cleaning liquid for semiconductor substrates with a change in the pH of the cleaning liquid caused by dilution being suppressed. A cleaning liquid of the invention is a cleaning liquid for semiconductor substrates that contains a chelating agent, and an acidity constant (pKa) of the chelating agent and a pH of the cleaning liquid satisfy a condition defined by Formula (A):

pKa−1<pH<pKa+1 (A)

### CROSS-REFERENCE TO RELATED APPLICATIONS

This application is a Continuation of PCT International Application No. PCT/JP2020/006200 filed on Feb. 18, 2020, which claims priority under 35 U.S.C. § 119(a) to Japanese Patent Application No. 2019-058577 filed on Mar. 26, 2019 and Japanese Patent Application No. 2019-129040 filed on Jul. 11, 2019. Each of the above applications are hereby expressly incorporated by reference, in its entirety, into the present application.

### BACKGROUND OF THE INVENTION

The present invention relates to a cleaning liquid used in cleaning of semiconductor substrates.

Semiconductor devices such as charge-coupled devices (CCDs) and memories are manufactured by forming fine electronic circuit patterns on substrates using the photolithography technology. Specifically, a semiconductor device is manufactured by forming a resist film on a laminate including a metal film which is a wiring material, an etching stop layer and an interlayer dielectric layer on a substrate and carrying out a photolithography step and a dry etching step (e.g., plasma etching).

In some cases, a dry etching residue (for instance, metal components such as titanium-based metal derived from a metallic hard mask, or organic components derived from a photoresist film) remains on a substrate having undergone the dry etching step.

In manufacture of semiconductor devices, a chemical mechanical polishing (CMP) process is sometimes carried out to planarize a surface of a substrate having a metal wiring film, a barrier metal, an insulating film and the like by use of an abrasive slurry containing fine abrasive particles (e.g., silica, alumina). In the CMP process, metal components derived from the fine abrasive particles used in the CMP process and from the metal wiring film, the barrier metal or the like having been polished easily remain on the surface of the semiconductor substrate after polishing.

Since those residues may cause a short-circuit between wires and affect electrical properties of a semiconductor, a cleaning step for removing the residues from the surface of the semiconductor substrate is carried out.

For instance, JP 2018-139307 A describes a cleaning liquid for a substrate for semiconductor devices, the cleaning liquid containing (A) a chelating agent, (B) a specific diamine compound and (C) water and having a pH of not less than 8 but not more than 14.

### SUMMARY OF THE INVENTION

The present inventors have studied a cleaning liquid for semiconductor substrates by reference to JP 2018-139307 A and as a result found that, while such cleaning liquids are usually manufactured and sold in the form of a concentrated liquid containing less water than when used in view of costs of raw materials, storage and transportation as well as improvement in temporal stability of residue removal performance, the pH values of the cleaning liquids may greatly change because of dilution with water or the like to the concentration suitable for cleaning of substrates, resulting in a variation in residue removal performance.

An object of the present invention is to provide a cleaning liquid for semiconductor substrates with a change in the pH of the cleaning liquid caused by dilution being suppressed.

The present inventors found that the above object can be attained with the following configuration.

[1] A cleaning liquid for semiconductor substrates, the cleaning liquid containing a chelating agent,

wherein an acidity constant (pKa) of the chelating agent and a pH of the cleaning liquid satisfy a condition defined by Formula (A) described later.

[2] The cleaning liquid according to [1],

wherein the chelating agent has at least one coordination group selected from a carboxy group and a phosphonic acid group.

[3] The cleaning liquid according to [1] or [2],

wherein the chelating agent includes at least one selected from diethylenetriaminepentaacetic acid, ethylenediamine tetraacetic acid, iminodiacetic acid, glycine, β-alanine, arginine, citric acid, tartaric acid, 1-hydroxyethylidene-1,1′-diphosphonic acid, and ethylenediamine tetra(methylenephosphonic acid).

[4] The cleaning liquid according to any one of [1] to [3],

wherein the cleaning liquid contains two or more chelating agents included in the chelating agent.

[5] The cleaning liquid according to [4],

wherein a ratio of a content of one chelating agent of the two or more chelating agents to a content of another chelating agent thereof is 1 to 5000 in mass ratio.

[6] The cleaning liquid according to any one of [1] to [5],

wherein a content of the chelating agent is 0.01 to 30 mass % based on a total mass of the cleaning liquid.

[7] The cleaning liquid according to any one of [1] to [6],

wherein the cleaning liquid further contains at least one component selected from a surfactant and an anticorrosive.

[8] The cleaning liquid according to [7],

wherein the anticorrosive includes at least one selected from the group consisting of a heterocyclic compound, a hydroxylamine compound, an ascorbic acid compound, and a catechol compound.

[9] The cleaning liquid according to [8],

wherein the heterocyclic compound includes at least one selected from the group consisting of an azole compound, a pyridine compound, a pyrazine compound, a pyrimidine compound, a piperazine compound, and a cyclic amidine compound.

[10] The cleaning liquid according to any one of [7] to [9],

wherein the anticorrosive includes at least one selected from the group consisting of a hydroxylamine compound, an ascorbic acid compound, and a catechol compound.

[11] The cleaning liquid according to any one of [1] to [10],

wherein the cleaning liquid further contains a surfactant and a basic organic compound.

[12] The cleaning liquid according to any one of [7] to [11],

wherein the surfactant includes an anionic surfactant.

[13] The cleaning liquid according to [12],

wherein the anionic surfactant includes at least one selected from the group consisting of a phosphoric acid ester-based surfactant, a phosphonic acid-based surfactant, a sulfonic acid-based surfactant, and a carboxylic acid-based surfactant.

[14] The cleaning liquid according to [12] or [13],

wherein the chelating agent includes a carboxylic acid-based chelating agent having a carboxy group, and the anionic surfactant includes at least one selected from the group consisting of a phosphoric acid ester-based surfactant, a phosphonic acid-based surfactant, a sulfonic acid-based surfactant, and a carboxylic acid-based surfactant.

[15] The cleaning liquid according to [12] or [13],

wherein the chelating agent includes a phosphonic acid-based chelating agent having a phosphonic acid group, and the anionic surfactant includes at least one selected from the group consisting of a phosphoric acid ester-based surfactant, a phosphonic acid-based surfactant, and a sulfonic acid-based surfactant.

[16] The cleaning liquid according to any one of [7] to [15],

wherein the surfactant includes a nonionic surfactant.

[17] The cleaning liquid according to any one of [1] to [10],

wherein the cleaning liquid further contains a pH adjuster.

[18] The cleaning liquid according to any one of [1] to [17],

wherein the cleaning liquid has a pH of 7.5 to 12.0 at 25° C.

[19] The cleaning liquid according to any one of [1] to [18],

wherein the cleaning liquid has a pH of 8.0 to 12.0 at 25° C.

[20] The cleaning liquid according to any one of [1] to [19], further containing water.
[21] The cleaning liquid according to any one of [1] to [20],

wherein a content of metal in the cleaning liquid is not more than 100 ppb by mass based on a total mass of the cleaning liquid.

[22] The cleaning liquid according to any one of [1] to [21],

wherein a content of particles with a particle size of 0.4 μm or more in the cleaning liquid is not more than 1000 particles per milliliter of the cleaning liquid.

[23] The cleaning liquid according to any one of [1] to [22],

wherein the cleaning liquid is used in cleaning of semiconductor substrates having undergone a chemical mechanical polishing process.

The present invention can provide a cleaning liquid for semiconductor substrates with a change in the pH of the cleaning liquid caused by dilution being suppressed.

### DETAILED DESCRIPTION OF THE INVENTION

One exemplary embodiment of the invention is described below.

In this specification, a numerical range expressed in the form of “A to B” should read as a range including both the values A and B as the range's lower and upper limits, respectively.

In this specification, when a certain component comprising two or more types is present, the “content” of the certain component means the total content of the two or more types.

In this specification, “ppm” means “parts per million (10⁻⁶),” “ppb” means “parts per billion (10⁻⁹),” and “ppt” means “parts per trillion (10⁻¹²).”

In compounds described in this specification, isomers (compounds with the same number of atoms but different structures), optical isomers, and isotopes may be included unless particularly limited. As isomers and isotopes, only one type or plural types may be included.

### [Cleaning Liquid]

The cleaning liquid of the invention (hereinafter also simply called “cleaning liquid”) is a cleaning liquid for semiconductor substrates, the cleaning liquid containing a chelating agent,

wherein an acidity constant (pKa) of the chelating agent and a pH of the cleaning liquid satisfy the condition defined by Formula (A):

pKa−1<pH<pKa+1 (A)

Since the cleaning liquid of the invention has the foregoing configuration, it is possible to suppress a change in the pH of the cleaning liquid even through dilution for use or other purposes, and owing to this, a variation in residue removal performance depending on the dilution ratio can be suppressed, thus providing the cleaning liquid having excellent stability in terms of residue removal performance.

Note that the “cleaning liquid for semiconductor substrates” means a cleaning liquid used in cleaning of semiconductor substrates.

Each component contained in the cleaning liquid is described below.

### [Chelating Agent]

The chelating agent used in the cleaning liquid is a compound that has a function of chelating with metal contained in a residue in a step of cleaning a semiconductor substrate. In particular, a compound having in the molecule two or more functional groups (coordination groups) that form coordinate bonds with metal ions.

The cleaning liquid of the invention is characterized in containing at least one chelating agent having the pKa satisfying the relationship of Formula (A) above with respect to the pH of the cleaning liquid.

When the chelating agent has plural pKa values, it suffices if one of the plural pKa values satisfies the relationship of Formula (A) above with respect to the pH of the cleaning liquid.

Chelating agents satisfying the relationship of Formula (A) above may be used singly or in combination of two or more. A chelating agent satisfying the relationship of Formula (A) above and another chelating agent not satisfying the relationship of Formula (A) above may be used in combination.

Examples of the coordination group that the chelating agent has include an acid group and a cationic group. Examples of the acid group include a carboxy group, a phosphonic acid group, a sulfo group, and a phenolic hydroxy group. One example of the cationic group is an amino group.

The chelating agent preferably has an acid group as the coordination group and more preferably has at least one coordination group selected from a carboxy group and a phosphonic acid group.

Examples of the chelating agent include an organic chelating agent and an inorganic chelating agent.

The organic chelating agent is a chelating agent constituted of an organic compound, and examples thereof include a carboxylic acid-based chelating agent having a carboxy group as the coordination group, and a phosphonic acid-based chelating agent having a phosphonic acid group as the coordination group.

Examples of the inorganic chelating agent include condensed phosphoric acid and salts thereof.

For the chelating agent, an organic chelating agent is preferred, and an organic chelating agent having at least one coordination group selected from a carboxy group and a phosphonic acid group is more preferred.

For the chelating agent, a low molecular weight chelating agent is preferred. The molecular weight of the low molecular weight chelating agent is preferably not more than 600, more preferably not more than 450 and even more preferably not more than 300.

When the chelating agent is an organic chelating agent, the number of carbon atoms is preferably not more than 15, more preferably not more than 12 and even more preferably not more than 8.

### (Carboxylic Acid-Based Chelating Agent)

The carboxylic acid-based chelating agent is a chelating agent having a carboxy group as the coordination group in the molecule, and examples thereof include an aminopolycarboxylic acid-based chelating agent, an amino acid-based chelating agent, a hydroxy carboxylic acid-based chelating agent, and an aliphatic carboxylic acid-based chelating agent.

Examples of the aminopolycarboxylic acid-based chelating agent include butylene diamine tetraacetic acid, diethylenetriamine pentaacetic acid (DTPA), ethylenediamine tetrapropionic acid, triethylenetetramine hexacetic acid, 1,3-diamino-2-hydroxypropane-N,N,N′,N′-tetraacetic acid, propylenediamine tetraacetic acid, ethylenediamine tetraacetic acid (EDTA), trans-1,2-diaminocyclohexane tetraacetic acid, ethylenediamine diacetic acid, ethylenediamine dipropionic acid, 1,6-hexamethylene-diamine-N,N,N′,N′-tetraacetic acid, N,N-bis(2-hydroxybenzyl)ethylenediamine-N,N-diacetic acid, diaminopropane tetraacetic acid, 1,4,7,10-tetraazacyclododecane-tetraacetic acid, diaminopropanol tetraacetic acid, (hydroxyethyl)ethylenediamine triacetic acid, and iminodiacetic acid (IDA).

Of these, diethylenetriamine pentaacetic acid (DTPA), ethylenediamine tetraacetic acid (EDTA), trans-1,2-diaminocyclohexane tetraacetic acid, or iminodiacetic acid (IDA) is preferable.

Examples of the amino acid-based chelating agent include glycine, serine, alanine, lysine, leucine, isoleucine, cystine, cysteine, ethionine, threonine, tryptophan, tyrosine, valine, histidine, histidine derivatives, asparagine, aspartic acid, glutamine, glutamic acid, arginine, proline, methionine, phenylalanine, compounds described in paragraphs [0021] to of JP 2016-086094 A, and salts thereof. The alanine may be α-alanine (2-aminopropionic acid) or ρ-alanine (3-aminopropionic acid), and β-alanine is preferred. For the histidine derivatives, the compounds described in JP 2015-165561 A, JP 2015-165562 A and the like can be applied, and the contents thereof are incorporated in the present specification. Examples of the salts include alkali metal salts such as a sodium salt and a potassium salt, ammonium salts, carbonates, and acetates.

Examples of the hydroxy carboxylic acid-based chelating agent include malic acid, citric acid, glycolic acid, gluconic acid, heptonic acid, tartaric acid, and lactic acid, with citric acid or tartaric acid being preferred.

Examples of the aliphatic carboxylic acid-based chelating agent include oxalic acid, malonic acid, succinic acid, glutaric acid, adipic acid, pimelic acid, sebacic acid, and maleic acid.

For the carboxylic acid-based chelating agent, the aminopolycarboxylic acid-based chelating agent, the amino acid-based chelating agent, or the hydroxy carboxylic acid-based chelating agent is preferred, and diethylenetriamine pentaacetic acid (DTPA), ethylenediamine tetraacetic acid (EDTA), trans-1,2-diaminocyclohexane tetraacetic acid, iminodiacetic acid (IDA), arginine, glycine, β-alanine, citric acid, tartaric acid, or oxalic acid is more preferred.

### (Phosphonic Acid-Based Chelating Agent)

The phosphonic acid-based chelating agent is a chelating agent having at least one phosphonic acid group in the molecule. Examples of the phosphonic acid-based chelating agent include compounds represented by General Formulae [1], [2] and [3] below.

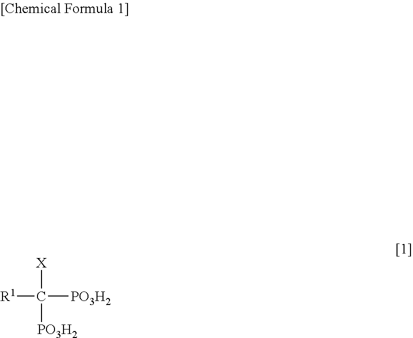

In the formula, X represents a hydrogen atom or a hydroxy group, and R¹ represents a hydrogen atom or an alkyl group having 1 to 10 carbon atoms.

The alkyl group having 1 to 10 carbon atoms represented by R¹ in General Formula [1] may be any of linear, branched and cyclic groups. Examples of the alkyl group having 1 to 10 carbon atoms represented by R¹ include a methyl group, an ethyl group, an n-propyl group, an isopropyl group, an n-butyl group, an isobutyl group, a sec-butyl group, a tert-butyl group, a cyclobutyl group, an n-pentyl group, an isopentyl group, a sec-pentyl group, a tert-pentyl group, a neopentyl group, a 2-methylbutyl group, a 1,2-dimethylpropyl group, a 1-ethylpropyl group, a cyclopentyl group, an n-hexyl group, an isohexyl group, a sec-hexyl group, a tert-hexyl group, a neohexyl group, a 2-methylpentyl group, a 1,2-dimethylbutyl group, a 2,3-dimethylbutyl group, a 1-ethylbutyl group, a cyclohexyl group, an n-heptyl group, an isoheptyl group, a sec-heptyl group, a tert-heptyl group, a neoheptyl group, a cycloheptyl group, an n-octyl group, an isooctyl group, a sec-octyl group, a tert-octyl group, a neooctyl group, a 2-ethylhexyl group, a cyclooctyl group, an n-nonyl group, an isononyl group, a sec-nonyl group, a tert-nonyl group, a neononyl group, a cyclononyl group, an n-decyl group, an isodecyl group, a sec-decyl group, a tert-decyl group, a neodecyl group, a cyclodecyl group, a bornyl group, a menthyl group, an adamantyl group, and a decahydronaphthyl group.

For R¹ in General Formula [1], an alkyl group having 1 to 10 carbon atoms is preferred, and a methyl group, an ethyl group, an n-propyl group, or an isopropyl group is more preferred.

It should be noted that n- represents a normal-type in specific examples of an alkyl group described in the present specification.

For X in General Formula [1], a hydroxy group is preferred.

For the phosphonic acid-based chelating agent represented by General Formula [1], preferred is ethylidenediphosphonic acid, 1-hydroxyethylidene-1,1′-diphosphonic acid (HEDP), 1-hydroxypropylidene-1,1′-diphosphonic acid, or 1-hydroxybutylidene-1,1′-diphosphonic acid.

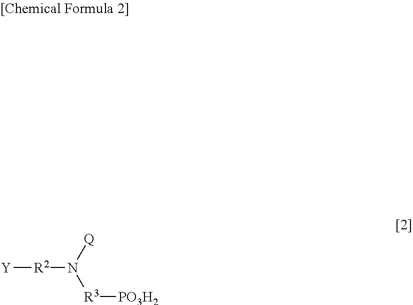

In the formula, Q represents a hydrogen atom or —R³—PO₃H₂, R² and R³ each independently represent an alkylene group, and Y represents a hydrogen atom, —R³—PO₃H₂, or a group represented by General Formula [4] below.

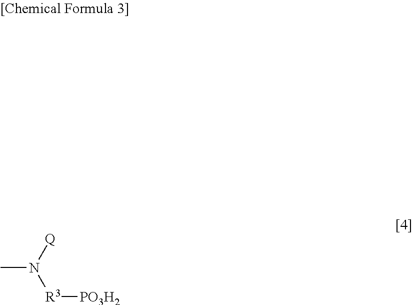

In the formula, Q and R³ are the same as those in General Formula [2].

Examples of the alkylene group represented by R² in General Formula [2] include a linear or branched alkylene group having 1 to 12 carbon atoms, and more specifically, a methylene group, an ethylene group, a propylene group, a trimethylene group, an ethylmethylene group, a tetramethylene group, a 2-methylpropylene group, a 2-methyltrimethylene group, an ethylethylene group, a pentamethylene group, a 2,2-dimethyltrimethylene group, a 2-ethyltrimethylene group, a hexamethylene group, a heptamethylene group, an octamethylene group, a 2-ethylhexamethylene group, a nonamethylene group, a decamethylene group, an undecamethylene group, and a dodecamethylene group.

For the alkylene group represented by R², a linear or branched alkylene group having 1 to 6 carbon atoms is preferred, and an ethylene group is more preferred.

Examples of the alkylene group represented by R³ in General Formulae [2] and [4] include a linear or branched alkylene group having 1 to 10 carbon atoms, more specifically, an alkylene group having 1 to 10 carbon atoms among examples of the linear or branched alkylene group having 1 to 12 carbon atoms listed as examples of the alkylene group represented by R².

For the alkylene group represented by R³, a methylene group or an ethylene group is preferred, and a methylene group is more preferred.

For Q in General Formulae [2] and [4], —R³—PO₃H₂ is preferred.

For Y in General Formula [2], —R³—PO₃H₂ or a group represented by General Formula [4] is preferred, and a group represented by General Formula [4] is more preferred.

For the phosphonic acid-based chelating agent represented by General Formula [2], preferred is ethylaminobis(methylenephosphonic acid), dodecylaminobis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(methylenephosphonic acid) (EDTPO), ethylenediamine tetra(ethylenephosphonic acid), 1,3-propylenediamine tetra(methylenephosphonic acid) (PDTMP), 1,2-diaminopropane tetra(methylenephosphonic acid), or 1,6-hexamethylenediamine tetra(methylenephosphonic acid).

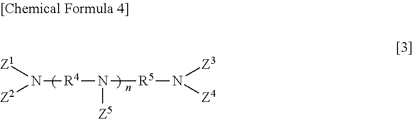

In the formula, R⁴ and R⁵ each independently represent an alkylene group having 1 to 4 carbon atoms, n represents an integer of 1 to 4, and at least four of Z¹ to Z⁴ and n moieties of Z⁵s represent an alkyl group having a phosphonic acid group while the remainder represents an alkyl group.

The alkylene group having 1 to 4 carbon atoms represented by R⁴ and R⁵ in General Formula [3] may be a linear or branched group. Examples of the alkylene group having 1 to 4 carbon atoms represented by R⁴ and R⁵ include a methylene group, an ethylene group, a propylene group, a trimethylene group, an ethylmethylene group, a tetramethylene group, a 2-methylpropylene group, a 2-methyltrimethylene group, and an ethylethylene group, with an ethylene group being preferred.

For n in General Formula [3], 1 or 2 is preferred.

Examples of an alkyl group in the alkyl group and the alkyl group having a phosphonic acid group represented by Z¹ to Z⁵ in General Formula [3] include a linear or branched alkyl group having 1 to 4 carbon atoms, more specifically, a methyl group, an ethyl group, an n-propyl group, an isopropyl group, an n-butyl group, an isobutyl group, a sec-butyl group, and a tert-butyl group, with a methyl group being preferred.

The number of phosphonic acid groups in the alkyl group having a phosphonic acid group represented by Z¹ to Z⁵ is preferably one or two and more preferably one.

Examples of the alkyl group having a phosphonic acid group represented by Z¹ to Z⁵ include a linear or branched alkyl group with 1 to 4 carbon atoms having one or two phosphonic acid groups. More specifically, examples thereof include a (mono)phosphonomethyl group, a (mono)phosphonoethyl group, a (mono)phosphono-n-propyl group, a (mono)phosphonoisopropyl group, a (mono)phosphono-n-butyl group, a (mono)phosphonoisobutyl group, a (mono)phosphono-sec-butyl group, a (mono)phosphono-tert-butyl group, a diphosphonomethyl group, a diphosphonoethyl group, a diphosphono-n-propyl group, a diphosphonoisopropyl group, a diphosphono-n-butyl group, a diphosphonoisobutyl group, a diphosphono-sec-butyl group, and a diphosphono-tert-butyl group. Of these, a (mono)phosphonomethyl group or a (mono)phosphonoethyl group is preferred, and a (mono)phosphonomethyl group is more preferred.

For Z¹ to Z⁵ in General Formula [3], it is preferable that all of Z¹ to Z⁴ and n moieties of Z⁵s be the foregoing alkyl groups having a phosphonic acid group.

For the phosphonic acid-based chelating agent represented by General Formula [3], preferred is diethylenetriamine penta(methylenephosphonic acid) (DEPPO), diethylenetriamine penta(ethylenephosphonic acid), triethylenetetramine hexa(methylenephosphonic acid), or triethylenetetramine hexa(ethylenephosphonic acid).

For the phosphonic acid-based chelating agent used in the cleaning liquid, not only the phosphonic acid-based chelating agents represented by General Formulae [1], [2] and [3] above but also the compounds described in paragraphs [0026] to [0036] of the description of WO 2018/020878 and the compounds ((co)polymers) described in paragraphs [0031] to [0046] of the description of WO 2018/030006 can be applied, and the contents thereof are incorporated in the present description.

For the phosphonic acid-based chelating agent used in the cleaning liquid, those compounds listed as preferable specific examples of the phosphonic acid-based chelating agents represented by General Formulae [1], [2] and [3] above are preferred, HEDP, NTPO, EDTPO, or DEPPO is more preferred, and HEDP or EDTPO is even more preferred.

The phosphonic acid-based chelating agents may be used singly or in combination of two or more.

A commercial phosphonic acid-based chelating agent may contain water such as distilled water, deionized water and ultrapure water in addition to a phosphonic acid-based chelating agent, and it is no problem to use such a phosphonic acid-based chelating agent containing water.

Examples of the condensed phosphoric acid and salts thereof which are the inorganic chelating agents include pyrophosphoric acid and salts thereof, metaphosphoric acid and salts thereof, tripolyphosphoric acid and salts thereof, and hexametaphosphoric acid and salts thereof.

For the chelating agent, preferred is DTPA, EDTA, trans-1,2-diaminocyclohexane tetraacetic acid, IDA, arginine, glycine, β-alanine, citric acid, tartaric acid, oxalic acid, HEDP, NTPO, EDTPO, or DEPPO, and more preferred is diethylenetriaminepentaacetic acid, ethylenediamine tetraacetic acid, iminodiacetic acid, glycine, β-alanine, arginine, citric acid, tartaric acid, 1-hydroxyethylidene-1,1′-diphosphonic acid (HEDP), or ethylenediamine tetra(methylenephosphonic acid) (EDTPO).

The chelating agents may be used alone or in combination of two or more, and the use of a combination of two or more is favorable. In particular, it is preferable that, of two or more chelating agents, one be the carboxylic acid-based chelating agent having a carboxy group and another one be the phosphonic acid-based chelating agent having a phosphonic acid group.

For the combination of two or more chelating agents, preferred is a combination of at least one carboxylic acid-based chelating agent having a carboxy group selected from arginine, citric acid and tartaric acid and at least one phosphonic acid-based chelating agent having a phosphonic acid group selected from 1-hydroxyethylidene-1,1′-diphosphonic acid and ethylenediamine tetra(methylenephosphonic acid).

When the cleaning liquid contains two or more chelating agents, the ratio between their contents is not particularly limited; however, the ratio of the content of one chelating agent to the content of another chelating agent is preferably 1 to 5000, more preferably 1 to 3000, even more preferably 5 to 1000, and particularly preferably 10 to 500 in mass ratio. Note that when the cleaning liquid contains three or more chelating agents, the ratio between the contents of two out of three or more chelating agents has the foregoing relationship.

The chelating agent content (the total content when two or more chelating agents are contained) of the cleaning liquid is not particularly limited and is preferably not less than 0.001 mass %, more preferably not less than 0.01 mass % and even more preferably not less than 0.05 mass % based on the total mass of the cleaning liquid because this leads to more excellent performance in suppressing a change in the pH caused by dilution. The upper limit of the chelating agent content (the total content when two or more chelating agents are contained) is not particularly limited and is preferably not more than 30 mass %, more preferably not more than 20 mass % and even more preferably not more than 10 mass % based on the total mass of the cleaning liquid because temporal stability associated with instability of solubility is excellent.

### [Water]

The cleaning liquid preferably contains water as a solvent. The type of water used in the cleaning liquid is not particularly limited as long as it has no bad influence on a semiconductor substrate, and distilled water, deionized water and pure water (ultrapure water) are usable. Pure water is preferred because it hardly contains impurities and its influence on a semiconductor substrate is smaller in a semiconductor substrate manufacturing process.

The water content of the cleaning liquid is not particularly limited and is for instance 1 to 99 mass % based on the total mass of the cleaning liquid.

### [Surfactant, Anticorrosive (Component B)]

The cleaning liquid may further contain at least one component (hereinafter also referred to as “component B”) selected from a surfactant and an anticorrosive as needed.

The surfactant and the anticorrosive that may be contained as the component B in the cleaning liquid are described below.

### (Surfactant)

The cleaning liquid may contain a surfactant.

The surfactant is not particularly limited as long as it is a compound having a hydrophilic group and a hydrophobic group (lipophilic group) in the molecule, and examples thereof include an anionic surfactant, a cationic surfactant, a nonionic surfactant, and an amphoteric surfactant.

It is preferable for the cleaning liquid to contain the surfactant because this leads to more excellent performance in preventing metal corrosion and more excellent removability of fine abrasive particles.

In many cases, the surfactant has a hydrophobic group selected from an aliphatic hydrocarbon group, an aromatic hydrocarbon group, and combinations thereof. The hydrophobic group that the surfactant has is not particularly limited; when the hydrophobic group includes an aromatic hydrocarbon group, the hydrophobic group including an aromatic hydrocarbon group has preferably 6 or more carbon atoms and more preferably 10 or more carbon atoms. When the hydrophobic group includes no aromatic hydrocarbon group and is constituted only of an aliphatic hydrocarbon group, the hydrophobic group has preferably 9 or more carbon atoms, more preferably 13 or more carbon atoms, and even more preferably 16 or more carbon atoms. The upper limit of the number of carbon atoms of the hydrophobic group is not particularly limited and is preferably not more than 20 and more preferably not more than 18.

### —Anionic Surfactant—

Examples of the anionic surfactant that is usable in the cleaning liquid include a phosphoric acid ester-based surfactant having a phosphoric acid ester group, a phosphonic acid-based surfactant having a phosphonic acid group, a sulfonic acid-based surfactant having a sulfo group, a carboxylic acid-based surfactant having a carboxy group, and a sulfuric acid ester-based surfactant having a sulfuric acid ester group, with those groups each acting as a hydrophilic group (acid group).

### <Phosphoric Acid Ester-based Surfactant>

Examples of the phosphoric acid ester-based surfactant include phosphoric acid ester (alkyl ether phosphoric acid ester), polyoxyalkylene ether phosphoric acid ester, and salts thereof. While the phosphoric acid ester and the polyoxyalkylene ether phosphoric acid ester usually include both a monoester and a diester, a monoester or a diester may be used alone.

Examples of the salts of the phosphoric acid ester-based surfactant include a sodium salt, a potassium salt, an ammonium salt, and an organic amine salt.

A monovalent alkyl group that the phosphoric acid ester and the polyoxyalkylene ether phosphoric acid ester have is not particularly limited and is preferably an alkyl group having 2 to 24 carbon atoms and more preferably an alkyl group having 6 to 18 carbon atoms.

A divalent alkylene group that the polyoxyalkylene ether phosphoric acid ester has is not particularly limited and is preferably an alkylene group having 2 to 6 carbon atoms and more preferably an ethylene group or a 1,2-propanediyl group. The number of repeats of an oxyalkylene group in the polyoxyalkylene ether phosphoric acid ester is preferably 1 to 12 and more preferably 1 to 6.

For the phosphoric acid ester-based surfactant, preferred is octyl phosphoric acid ester, lauryl phosphoric acid ester, tridecyl phosphoric acid ester, polyoxyethylene octyl ether phosphoric acid ester, polyoxyethylene lauryl ether phosphoric acid ester, or polyoxyethylene tridecyl ether phosphoric acid ester, more preferred is octyl phosphoric acid ester, lauryl phosphoric acid ester, or tridecyl phosphoric acid ester, and even more preferred is lauryl phosphoric acid ester.

Besides, for the phosphoric acid ester-based surfactant, polyoxyethylene octyl ether phosphoric acid ester, polyoxyethylene lauryl ether phosphoric acid ester, or polyoxyethylene tridecyl ether phosphoric acid ester is preferred, and polyoxyethylene lauryl ether phosphoric acid ester is more preferred from the viewpoint of an improvement in hydrophilicity, which contributes to an improvement in wettability of a surface, resulting in excellent cleaning properties.

For the phosphoric acid ester-based surfactant, the compounds described in paragraphs [0012] to [0019] of JP 2011-40502 A can also be applied, and the contents thereof are incorporated in the present description.

### <Phosphonic Acid-Based Surfactant>

Examples of the phosphonic acid-based surfactant include alkyl phosphonic acid and polyvinyl phosphonic acid as well as aminomethyl phosphonic acid described in, for example, JP 2012-57108 A.

### <Sulfonic Acid-Based Surfactant>

Examples of the sulfonic acid-based surfactant include alkyl sulfonic acid, alkylbenzene sulfonic acid, alkylnaphthalene sulfonic acid, alkyl diphenyl ether disulphonic acid, alkyl methyl taurine, sulfosuccinic acid diester, polyoxyalkylene alkyl ether sulfonic acid, and salts thereof.

A monovalent alkyl group that the sulfonic acid-based surfactant has is not particularly limited and is preferably an alkyl group having 2 to 24 carbon atoms and more preferably an alkyl group having 6 to 18 carbon atoms.

A divalent alkylene group that the polyoxyalkylene alkyl ether sulfonic acid has is not particularly limited and is preferably an ethylene group or a 1,2-propanediyl group. The number of repeats of an oxyalkylene group in the polyoxyalkylene alkyl ether sulfonic acid is preferably 1 to 12 and more preferably 1 to 6.

Specific examples of the sulfonic acid-based surfactant include hexanesulfonic acid, octanesulfonic acid, decanesulfonic acid, dodecanesulfonic acid, toluenesulfonic acid, cumenesulfonic acid, octylbenzenesulfonic acid, dodecylbenzenesulfonic acid (DBSA), dinitrobenzenesulfonic acid (DNBSA), and lauryl dodecylphenyl ether disulfonic acid (LDPEDSA). Of these, dodecanesulfonic acid, DBSA, DNBSA, or LDPEDSA is preferred, and DBSA, DNBSA, or LDPEDSA is more preferred.

### [Carboxylic Acid-Based Surfactant>

Examples of the carboxylic acid-based surfactant include alkyl carboxylic acid, alkylbenzene carboxylic acid, and polyoxyalkylene alkyl ether carboxylic acid, and salts thereof.

A monovalent alkyl group that the carboxylic acid-based surfactant has is not particularly limited and is preferably an alkyl group having 7 to 25 carbon atoms and more preferably an alkyl group having 11 to 17 carbon atoms.

A divalent alkylene group that the polyoxyalkylene alkyl ether carboxylic acid has is not particularly limited and is preferably an ethylene group or a 1,2-propanediyl group. The number of repeats of an oxyalkylene group in the polyoxyalkylene alkyl ether carboxylic acid is preferably 1 to 12 and more preferably 1 to 6.

Specific examples of the carboxylic acid-based surfactant include lauric acid, myristic acid, palmitic acid, stearic acid, polyoxyethylene lauryl ether acetic acid, and polyoxyethylene tridecyl ether acetic acid.

### <Sulfuric Acid Ester-based Surfactant>

Examples of the sulfuric acid ester-based surfactant include sulfuric acid ester (alkyl ether sulfuric acid ester), polyoxyalkylene ether sulfuric acid ester, and salts thereof.

A monovalent alkyl group that the sulfuric acid ester and the polyoxyalkylene ether sulfuric acid ester have is not particularly limited and is preferably an alkyl group having 2 to 24 carbon atoms and more preferably an alkyl group having 6 to 18 carbon atoms.

A divalent alkylene group that the polyoxyalkylene ether sulfuric acid ester has is not particularly limited and is preferably an ethylene group or a 1,2-propanediyl group. The number of repeats of an oxyalkylene group in the polyoxyalkylene ether sulfuric acid ester is preferably 1 to 12 and more preferably 1 to 6.

Specific examples of the sulfuric acid ester-based surfactant include lauryl sulfuric acid ester, myristyl sulfuric acid ester, and polyoxyethylene lauryl ether sulfuric acid ester.

### —Cationic Surfactant—

Examples of the cationic surfactant include primary to tertiary alkylamine salts (e.g., monostearyl ammonium chloride, distearyl ammonium chloride, and tristearyl ammonium chloride), and modified aliphatic polyamine (e.g., polyethylene polyamine).

### —Nonionic Surfactant—

Examples of the nonionic surfactant include polyoxyalkylene alkyl ether (e.g., polyoxyethylene stearyl ether), polyoxyalkylene alkenyl ether (e.g., polyoxyethylene oleyl ether), polyoxyethylene alkyl phenyl ether (e.g., polyoxyethylene nonyl phenyl ether), polyoxyalkylene glycol (e.g., polyoxypropylene polyoxyethylene glycol), polyoxyalkylene monoalkylate (monoalkyl fatty acid ester polyoxyalkylene) (e.g., polyoxyethylene monoalkylates such as polyoxyethylene monostearate and polyoxyethylene monooleate), polyoxyalkylene dialkylate (dialkyl fatty acid ester polyoxyalkylene) (e.g., polyoxyethylene dialkylates such as polyoxyethylene distearate and polyoxyethylene dioleate), bispolyoxyalkylene alkylamide (e.g., bispolyoxyethylene stearylamide), sorbitan fatty acid ester, polyoxyethylene sorbitan fatty acid ester, polyoxyethylene alkylamine, glycerine fatty acid ester, oxyethylene-oxypropylene block copolymer, acetylene glycol-based surfactant, and acetylene-based polyoxyethylene oxide.

Of these, polyoxyethylene monoalkylate or polyoxyethylene dialkylate is preferred, and polyoxyethylene dialkylate is more preferred.

### —Amphoteric Surfactant—

Examples of the amphoteric surfactant include carboxybetaine (e.g., alkyl-N,N-dimethylaminoacetic acid betaine and alkyl-N,N-dihydroxyethylaminoacetic acid betaine), sulfobetaine (e.g., alkyl-N,N-dimethylsulfoethylene ammonium betaine), imidazolinium betaine (e.g., 2-alkyl-N-carboxymethyl-N-hydroxyethylimidazolinium betaine), and alkylamine oxide (e.g., N,N-dimethylalkylamine oxide).

For the surfactant, the compounds described in paragraphs to [0096] of JP 2015-158662 A, paragraphs [0045] to [0046] of JP 2012-151273 A, and paragraphs [0014] to [0020] of JP 2009-147389 A can also be applied, and the contents thereof are incorporated in the present description.

The cleaning liquid preferably contains the anionic surfactant. The anionic surfactants may be used singly or in combination of two or more.

For the anionic surfactant, at least one selected from the group consisting of the phosphoric acid ester-based surfactant, the sulfonic acid-based surfactant, the phosphonic acid-based surfactant, and the carboxylic acid-based surfactant is preferred.

When the chelating agent is the carboxylic acid-based chelating agent, the anionic surfactant is preferably at least one selected from the group consisting of the phosphoric acid ester-based surfactant, the phosphonic acid-based surfactant, the sulfonic acid-based surfactant, and the carboxylic acid-based surfactant.

When the chelating agent is the phosphonic acid-based chelating agent, the anionic surfactant is preferably at least one selected from the group consisting of the phosphoric acid ester-based surfactant, the phosphonic acid-based surfactant, and the sulfonic acid-based surfactant.

As the anionic surfactant contained, the phosphoric acid ester-based surfactant or the sulfonic acid-based surfactant is preferred, and the phosphoric acid ester-based surfactant is more preferred.

Those surfactants may be used singly or in combination of two or more.

When the cleaning liquid contains the surfactant, the surfactant content (the total content when two or more surfactants are contained) is preferably 0.001 to 1 mass %, more preferably 0.001 to 0.5 mass % and even more preferably 0.003 to 0.5 mass % based on the total mass of the cleaning liquid.

Commercial products may be used as those surfactants.

### (Anticorrosive)

The cleaning liquid may contain an anticorrosive.

In the present specification, the anticorrosive is a compound that is not included in the chelating agents or the surfactants described above.

The anticorrosive usable for the cleaning liquid is not particularly limited, and examples thereof include a heterocyclic compound having a heterocyclic structure in the molecule, a hydroxylamine compound, ascorbic acid, and a catechol compound.

### —Heterocyclic Compound—

The cleaning liquid may contain a heterocyclic compound as the anticorrosive.

The heterocyclic compound is a compound having a heterocyclic structure in the molecule. The heterocyclic structure that the heterocyclic compound has is not particularly limited, and examples thereof include a heterocyclic ring in which at least one of atoms constituting the ring is a nitrogen atom (nitrogen-containing heterocyclic ring).

Examples of the heterocyclic compound having the nitrogen-containing heterocyclic ring include an azole compound, a pyridine compound, a pyrazine compound, a pyrimidine compound, a piperazine compound, and a cyclic amidine compound.

The azole compound is a compound having a five-membered heterocyclic ring containing at least one nitrogen atom and having aromatic properties.

The number of nitrogen atoms included in the five-membered heterocyclic ring of the azole compound is not particularly limited, and is preferably 1 to 4 and more preferably 1 to 3.

The azole compound may have a substituent on the five-membered heterocyclic ring. Examples of the substituent include a hydroxy group, a carboxy group, a mercapto group, an amino group, an alkyl group having 1 to 4 carbon atoms that may have an amino group, and a 2-imidazolyl group.

Examples of the azole compound include an imidazole compound in which one of atoms constituting an azole ring is a nitrogen atom, a pyrazole compound in which two of atoms constituting an azole ring are nitrogen atoms, a thiazole compound in which, of atoms constituting an azole ring, one is a nitrogen atom and another one is a sulfur atom, a triazole compound in which three of atoms constituting an azole ring are nitrogen atoms, and a tetrazole compound in which four of atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, and benzimidazole.

Examples of the pyrazole compound include pyrazole, 4-pyrazolecarboxylic acid, 1-methylpyrazole, 3-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, and 5-methylbenzotriazole.

Examples of the tetrazole compound include 1H-tetrazole(1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

For the azole compound, the triazole compound or the tetrazole compound is preferred, and 1,2,4-triazole, 5-aminotetrazole, or 1H-tetrazole is more preferred.

The pyridine compound is a compound having a six-membered heterocyclic ring (pyridine ring) containing one nitrogen atom and having aromatic properties.

The pyridine compound may have a substituent on the pyridine ring. Examples of the substituent include a hydroxy group, an amino group, a cyano group, an alkyl group having 1 to 4 carbon atoms, and an alkylamide group having 1 to 4 carbon atoms.

Examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having a six-membered heterocyclic ring (pyrazine ring) containing two nitrogen atoms at the para positions having aromatic properties, and the pyrimidine compound is a compound having a six-membered heterocyclic ring (pyrimidine ring) containing two nitrogen atoms at the meta positions and having aromatic properties.

The pyrazine compound and the pyrimidine compound may each have a substituent on the ring. Examples of the substituent include a hydroxy group, an amino group, a carboxy group, and an alkyl group having 1 to 4 carbon atoms that may have a hydroxyl group.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine, with pyrazine being preferred.

Examples of the pyrimidine compound include pyrimidine, 2-methylpyrimidine, 2-aminopyrimidine, and 4,6-dimethylpyrimidine, with 2-aminopyrimidine being preferred.

The piperazine compound is a compound having a six-membered heterocyclic ring (piperazine ring) in which opposed —CH— groups in a cyclohexane ring are substituted with nitrogen atoms. The piperazine compound is favorable because it leads to excellent storage stability of the cleaning liquid.

The piperazine compound may have a substituent on the piperazine ring. Examples of the substituent include a hydroxy group, an alkyl group having 1 to 4 carbon atoms that may have a hydroxy group, and an aryl group having 6 to 10 carbon atoms.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), and 1,4-bis(3-aminopropyl)piperazine (BAP), with preferred being piperazine, 1-methylpiperazine, 2-methylpiperazine, HEP, or BAP, and more preferred being HEP or BAP.

The cyclic amidine compound is a compound having a heterocyclic ring including an amidine structure (>N—C═N—) in the ring.

The number of atoms constituting the heterocyclic ring of the cyclic amidine compound is not particularly limited and is preferably 5 or 6 and more preferably 6.

The cyclic amidine compound may have a substituent on the heterocyclic ring. Examples of the substituent include an amino group, an oxo group, and an alkyl group having 1 to 4 carbon atoms. Further, two substituents on the heterocyclic ring may be bonded together to form a divalent linking group (preferably, an alkylene group having 3 to 6 carbon atoms).

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimido[1.2-a]azocine, 3,4,6,7,8,9-hexahydro-2H-pyrido[1.2-a]pyrimidine, 2,5,6,7-terahydro-3H-pyrrolo[1.2-a]imidazole, 3-ethyl-2,3,4,6,7,8,9,10-octahydropyrimido[1.2-a]azepine, and creatinine, with DBU or DBN being preferred.

Examples of the heterocyclic compound include, in addition to the foregoing examples, a compound having a five-membered heterocyclic ring with no aromatic properties such as 1,3-dimethyl-2-imidazolidinone or imidazolidinethione, and a compound having a seven-membered ring containing a nitrogen atom(s).

Examples of the compound having a seven-membered ring containing a nitrogen atom(s) include hexahydro-1H-1,4-diazepine, 1-methylhexahydro-1H-1,4-diazepine, 2-methylhexahydro-1H-1,4-diazepine, 6-methylhexahydro-1H-1,4-diazepine, 2,7-diazabicyclo[3.2.1]octane, and 1,3-diazabicyclo[3.2.2]nonane.

### —Hydroxylamine Compound—

The cleaning liquid may contain a hydroxylamine compound as the anticorrosive.

The hydroxylamine compound refers to at least one selected from the group consisting of hydroxylamine (NH₂OH), a hydroxylamine derivative, and their salts.

The hydroxylamine derivative refers to a compound of hydroxylamine (NH₂OH) obtained through substitution with at least one organic group.

A salt of hydroxylamine or a hydroxylamine derivative may be an inorganic or organic acid salt of hydroxylamine or a hydroxylamine derivative. For the salt of hydroxylamine or a hydroxylamine derivative, preferred is a salt thereof with an inorganic acid in which at least one non-metal selected from the group consisting of Cl, S, N and P is bonded to hydrogen, and more preferred is a hydrochloride, a sulfate, or a nitrate.

One example of the hydroxylamine compound is a compound represented by General Formula (5).

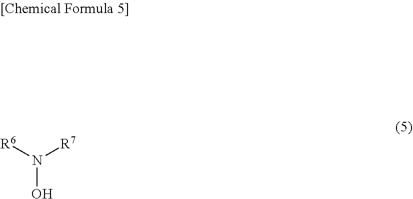

In the formula, R⁶ and R⁷ each independently represent a hydrogen atom or an alkyl group having 1 to 6 carbon atoms.

The alkyl group having 1 to 6 carbon atoms represented by R⁶ and R⁷ may be any of linear, branched and cyclic groups, and examples thereof include a methyl group, an ethyl group, an n-propyl group, an isopropyl group, an n-butyl group, an isobutyl group, a sec-butyl group, a tert-butyl group, a cyclobutyl group, an n-pentyl group, an isopentyl group, a sec-pentyl group, a tert-pentyl group, a neopentyl group, a 2-methylbutyl group, a 1,2-dimethylpropyl group, a 1-ethylpropyl group, a cyclopentyl group, an n-hexyl group, an isohexyl group, a sec-hexyl group, a tert-hexyl group, a neohexyl group, a 2-methylpentyl group, a 1,2-dimethylbutyl group, a 2,3-dimethylbutyl group, a 1-ethylbutyl group, and a cyclohexyl group.

For R⁶ and R⁷ in General Formula (5), an alkyl group having 1 to 6 carbon atoms is preferred, an ethyl group or an n-propyl group is more preferred, and an ethyl group is even more preferred.

Examples of the hydroxylamine compound include hydroxylamine, N-methylhydroxylamine, N,N-dimethylhydroxylamine, N-ethylhydroxylamine, N,N-diethylhydroxylamine (DEHA), N-n-propylhydroxylamine, N,N-di-n-propylhydroxylamine, N-isopropylhydroxylamine, N,N-diisopropylhydroxylamine, N-n-butylhydroxylamine, N,N-di-n-butylhydroxylamine, N-isobutylhydroxylamine, N,N-diisobutylhydroxylamine, N-sec-butylhydroxylamine, N,N-di-sec-butylhydroxylamine, N-tert-butylhydroxylamine, N,N-di-tert-butylhydroxylamine, N-cyclobutylhydroxylamine, N,N-dicyclobutylhydroxylamine, N-n-pentylhydroxylamine, N,N-di-n-pentylhydroxylamine, N-isopentylhydroxylamine, N,N-diisopentylhydroxylamine, N-sec-pentylhydroxylamine, N,N-di-sec-pentylhydroxylamine, N-tert-pentylhydroxylamine, N,N-di-tert-pentylhydroxylamine, N-neopentylhydroxylamine, N,N-dineopentylhydroxylamine, N-2-methylbutylhydroxylamine, N,N-bis(2-methylbutyl)hydroxylamine, N-1,2-dimethylpropylhydroxylamine, N,N-bis(1,2-dimethylpropyl)hydroxylamine, N-1-ethylpropylhydroxylamine, N,N-bis(1-ethylpropyl)hydroxylamine, N-cyclopentylhydroxylamine, N,N-dicyclopentylhydroxylamine, N-n-hexylhydroxylamine, N,N-di-n-hexylhydroxylamine, N-isohexylhydroxylamine, N,N-diisohexylhydroxylamine, N-sec-hexylhydroxylamine, N,N-di-sec-hexylhydroxylamine, N-tert-hexylhydroxylamine, N,N-di-tert-hexylhydroxylamine, N-neohexylhydroxylamine, N,N-dineohexylhydroxylamine, N-2-methylpentylhydroxylamine, N,N-bis(2-methylpentyl)hydroxylamine, N-1,2-dimethylbutylhydroxylamine, N,N-bis(1,2-dimethylbutyl)hydroxylamine, N-2,3-dimethylbutylhydroxylamine, N,N-bis(2,3-dimethylbutyl)hydroxylamine, N-1-ethylbutylhydroxylamine, N,N-bis(1-ethylbutyl)hydroxylamine, N-cyclohexylhydroxylamine, and N,N-dicyclohexylhydroxylamine.

Of these, N-ethylhydroxylamine, DEHA, or N-n-propylhydroxylamine is preferred, and DEHA is more preferred.

The hydroxylamine compounds may be used singly or in combination of two or more. As the hydroxylamine compound, a commercial product or a composite suitably formed by a known method may be used.

### —Ascorbic Acid Compound—

The cleaning liquid may contain an ascorbic acid compound as the anticorrosive.

The ascorbic acid compound refers to at least one selected from the group consisting of ascorbic acid, an ascorbic acid derivative, and their salts.

Examples of the ascorbic acid derivative include an ascorbic acid phosphoric acid ester, and an ascorbic acid sulfuric acid ester.

### —Catechol Compound—

The cleaning liquid may contain a catechol compound as the anticorrosive.

The catechol compound refers to at least one selected from the group consisting of pyrocatechol(benzene-1,2-diol), and a catechol derivative.

The catechol derivative refers to a compound of pyrocatechol obtained through substitution with at least one substituent. Examples of the substituent that the catechol derivative has include a hydroxy group, a carboxy group, a carboxylic acid ester group, a sulfo group, a sulfonic acid ester group, an alkyl group (preferably, an alkyl group having 1 to 6 carbon atoms, and more preferably, an alkyl group having 1 to 4 carbon atoms), and an aryl group (preferably a phenyl group). The carboxy group and the sulfo group that the catechol derivative has as substituents may be salts with a cation. The alkyl group and the aryl group that the catechol derivative has as substituents may further have a substituent.

Examples of the catechol compound include pyrocatechol, 4-tert-butylcatechol, pyrogallol, gallic acid, methyl gallate, 1,2,4-benzenetriol, and tiron.

An anticorrosive other than the heterocyclic compound, the hydroxylamine compound, the ascorbic acid and the catechol compound may be used as the anticorrosive for the cleaning liquid.

Exemplary other anticorrosives include sugars such as fructose, glucose, and ribose, polyols such as ethylene glycol, propylene glycol, and glycerin, polycarboxylic acids such as polyacrylic acid, polymaleic acid, and copolymers thereof, polyvinylpyrrolidone, cyanuric acid, barbituric acid and its derivatives, glucuronic acid, squaric acid, α-keto acid, adenosine and its derivatives, a purine compound and its derivatives, phenanthroline, ascorbic acid, resorcinol, hydroquinone, nicotinamide and its derivatives, flavonol and its derivatives, anthocyanin and its derivatives, and combinations thereof.

For the anticorrosive, the heterocyclic compound, the hydroxylamine compound, the ascorbic acid, or the catechol is preferred, the heterocyclic compound or the hydroxylamine compound is more preferred, the azole compound, the pyrimidine compound, the piperazine compound, the cyclic amidine compound, or the hydroxylamine compound is even more preferred, and the triazole compound, the tetrazole compound, the pyrimidine compound, the piperazine compound, the cyclic amidine compound, or the hydroxylamine compound is particularly preferred.

The anticorrosives may be used singly or in combination of two or more.

When the cleaning liquid contains the anticorrosive, the content thereof is preferably 0.01 to 10 mass %, more preferably 0.05 to 5 mass % and even more preferably 0.1 to 3 mass % based on the total mass of the cleaning liquid.

The cleaning liquid preferably contains the component B because this leads to excellent residue removal performance.

In particular, it is preferable for the cleaning liquid to contain both the surfactant and the anticorrosive as the component B because this leads to excellent performance in suppressing defects of a semiconductor substrate with respect to a cobalt-containing film.

The component B content (the total content of the surfactant and the anticorrosive) of the cleaning liquid is preferably 0.011 to 11 mass %, more preferably 0.051 to 5.2 mass % and even more preferably 0.08 to 4.5 mass % based on the total mass of the cleaning liquid.

The ratio of the component B content to the chelating agent content is preferably 0.01 to 3000, more preferably 0.1 to 400 and even more preferably 1 to 50 in mass ratio for the sake of achieving both anticorrosion properties and cleaning properties.

### [pH Adjuster]

The cleaning liquid may contain a pH adjuster for adjusting and maintaining the pH of the cleaning liquid. Examples of the pH adjuster include a basic compound and an acidic compound other than the foregoing components.

### (Basic Compound)

Examples of the basic compound include a basic organic compound and a basic inorganic compound.

### —Basic Organic Compound—

Examples of the basic organic compound that may be used include a quaternary ammonium compound, a monoamine compound, and a diamine compound.

Note that the quaternary ammonium compound, the monoamine compound and the diamine compound contained as the basic organic compound are different from the heterocyclic compound having the nitrogen-containing heterocyclic ring and the hydroxylamine compound described above.

### <Quaternary Ammonium Compound>

The quaternary ammonium compound is not particularly limited as long as it is a quaternary ammonium cation-containing compound in which a nitrogen atom is attached to four hydrocarbon groups (preferably, alkyl groups) through substitution.

Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate, with quaternary ammonium hydroxide being preferred.

One example of the quaternary ammonium compound is a compound represented by General Formula (6):

(R⁸)₄N⁺OH⁻ (6)

In the formula, R⁸ represents an alkyl group that may have a hydroxy group or a phenyl group as a substituent. Four R⁸s may be the same or different.

For the alkyl group represented by R⁸, an alkyl group having 1 to 4 carbon atoms is preferred, and a methyl group or an ethyl group is more preferred.

For the alkyl group that may have a hydroxy group or a phenyl group as represented by R⁸, preferred is a methyl group, an ethyl group, a propyl group, a butyl group, a 2-hydroxyethyl group, or a benzyl group, more preferred is a methyl group, an ethyl group, a propyl group, a butyl group, or a 2-hydroxyethyl group, and even more preferred is a methyl group, an ethyl group, or a 2-hydroxyethyl group.

Examples of the quaternary ammonium compound include tetramethylammonium hydroxide (TMAH), tetraethylammonium hydroxide (TEAH), tetrapropylammonium hydroxide (TPAH), tetrabutylammonium hydroxide (TBAH), 2-hydroxyethyl trimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide.

As examples of the quaternary ammonium compound other than the foregoing specific examples, the compounds described in paragraph [0021] of JP 2018-107353 A can be applied, and the contents thereof are incorporated in the present description.

For the quaternary ammonium compound used for the cleaning liquid, of the foregoing quaternary ammonium compounds, a compound other than TMAH is preferred, choline, TEAR, TPAH, TBAH, or bis(2-hydroxyethyl)dimethylammonium hydroxide is more preferred, and TBAH is even more preferred.

When the cleaning liquid contains the quaternary ammonium compound as the pH adjuster, the content thereof is preferably 0.05 to 10 mass % and more preferably 0.1 to 5 mass % based on the total mass of the cleaning liquid.

### <Monoamine Compound, Diamine Compound>

Examples of the monoamine compound and the diamine compound include an alkanolamine having at least one hydroxyalkyl group in the molecule, and a monoamine compound and a diamine compound each having at least one alkyl group in the molecule and having no hydroxyalkyl group and no nitrogen-containing ring.

Examples of the alkanolamine include monoethanolamine, 2-amino-2-methyl-1-propanol (AMP), diethanolamine, triethanolamine, diethylene glycol amine, tris(hydroxymethyl)aminomethane (Tris), dimethylbis(2-hydroxyethyl)ammonium hydroxide (AH212), 2-(2-hydroxyethyl)ethanol (AEE), and 2-(2-aminoethylamino)ethanol.

The cleaning liquid preferably contains the alkanolamine because this leads to excellent performance in suppressing defects with respect to a copper-containing film and a tungsten-containing film.

Examples of the monoamine compound and the diamine compound other than the alkanolamine include ethylamine, benzylamine, diethylamine, n-butylamine, 3-methoxypropylamine, tert-butylamine, n-hexylamine, cyclohexylamine, n-octylamine, 2-ethylhexylamine, and 4-(2-aminoethyl)morpholine (AEM).

For the monoamine compound, the compounds described in paragraphs [0034] to [0056] of the description of WO 2013/162020 can be applied, and the contents thereof are incorporated in the present description.

When the cleaning liquid contains the monoamine compound and the diamine compound as the pH adjuster, the content thereof is preferably 0.05 to 15 mass % and more preferably 0.5 to 12 mass % based on the total mass of the cleaning liquid.

As the pH adjuster that is the basic organic compound, the heterocyclic compound having the nitrogen-containing heterocyclic ring listed above as the anticorrosive may be used for adjusting the pH of the cleaning liquid. That is, the foregoing heterocyclic compound having the nitrogen-containing heterocyclic ring may have the function of the pH adjuster in addition to the function of the anticorrosive.

It is preferable for the cleaning liquid to contain the basic organic compound or the piperazine compound compared to the cyclic amidine compound described above as the pH adjuster or a compound having the function of the pH adjuster because of excellent storage stability of the cleaning liquid. In particular, the quaternary ammonium compound, the monoamine compound, or the diamine compound is more preferred, and the alkanolamine is even more preferred.

It is preferable for the cleaning liquid to further contain both the surfactant and the basic organic compound in addition to the chelating agent because this leads to more excellent performance in suppressing defects with respect to a copper-containing film and a cobalt-containing film.

In particular, as the basic organic compound, the quaternary ammonium compound, the monoamine compound, or the diamine compound is preferred, the quaternary ammonium compound or the alkanolamine is more preferred, and the alkanolamine is even more preferred.

### —Basic Inorganic Compound—

Examples of the basic inorganic compound include an alkali metal hydroxide, an alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

When the cleaning liquid contains the basic inorganic compound as the pH adjuster, the content thereof is preferably 0.03 to 15 mass % and more preferably 0.1 to 13 mass % based on the total mass of the cleaning liquid.

The cleaning liquid may contain, other than the foregoing compounds, at least one selected from the group consisting of nitro, nitroso, oxime, ketoxime, aldoxime, nitrone, lactam, isocyanide compounds, hydrazide compounds such as carbohydrazide, and urea, as the basic compound.

As the basic compound, the quaternary ammonium compound or the monoamine compound is preferred because they contain no metal ions and have less adverse effects on electrical properties of a semiconductor device.

Those basic compounds for use may be commercial products or composites suitably formed by a known method.

### (Acidic Compound)

The cleaning liquid may contain an acidic compound as the pH adjuster.

The acidic compound may be an inorganic or organic acid.

Examples of the inorganic acid include hydrochloric acid, sulfuric acid, sulfurous acid, nitric acid, nitrous acid, phosphoric acid, boric acid, and hexafluorophosphoric acid. Salts of the inorganic acids may also be used, and examples thereof include ammonium salts of the inorganic acids, more specifically, ammonium chloride, ammonium sulfate, ammonium sulfite, ammonium nitrate, ammonium nitrite, ammonium phosphate, ammonium borate, and ammonium hexafluorophosphate.

For the inorganic acid, phosphoric acid or a phosphate is preferred, and phosphoric acid is more preferred.

The organic acid is an organic compound having an acidic functional group and showing acidic properties (pH: less than 7.0) in an aqueous solution and is a compound that is not included in the chelating agents or the anticorrosives described above. Examples of the organic acid include lower aliphatic monocarboxylic acids (with 1 to 4 carbon atoms) such as formic acid, acetic acid, propionic acid and butyric acid.

As the acidic compound, a salt of the acidic compound may be used as long as it forms an acid or an acid ion (anion) in an aqueous solution. As the acidic compound, a commercial product or a composite suitably formed by a known method may be used.

The pH adjusters may be used singly or in combination of two or more.

When the cleaning liquid contains the pH adjuster, the content thereof is selected depending on the types and the amounts of other components and the pH of a target cleaning liquid, and is preferably 0.03 to 15 mass % and more preferably 0.1 to 13 mass % based on the total mass of the cleaning liquid.

### [Additives]

The cleaning liquid may optionally contain other additives than the foregoing components. Examples of such additives include a polymer, a fluorine compound, and an organic solvent.

For the polymer, the water-soluble polymers described in paragraphs [0043] to [0047] of JP 2016-171294 A can be applied, and the contents thereof are incorporated in the present description.

For the fluorine compound, the compounds described in paragraphs [0013] to [0015] of JP 2005-150236 A can be applied, and the contents thereof are incorporated in the present description.

For the organic solvent, any of known organic solvents may be used, and hydrophilic organic solvents such as alcohols and ketones are preferred. The organic solvents may be used singly or in combination of two or more.

The amounts of the polymer, fluorine compound and organic solvent for use are not particularly limited and may be suitably specified in the ranges that do not impair the effects of the invention.

Preferably, the cleaning liquid does not contain other components than the chelating agent, the component B, the pH adjuster, and water as above in order to further suppress the influence on metals forming layers of a semiconductor substrate. The phrase “not contain other components” means that the amount of such other components is at or below the detection limit, or even when such other components are contained, the amount thereof is a trace amount that does not cause any adverse effect on a semiconductor substrate to be subjected to cleaning.

The contents of the respective components above in the cleaning liquid can be measured by known methods such as gas chromatography-mass spectrometry (GC-MS), liquid chromatography-mass spectrometry (LC-MS), and ion-exchange chromatography (IC).

### [Physical Properties of Cleaning Liquid]

[pH]

The pH of the cleaning liquid of the present invention satisfies the relationship of Formula (A) above with respect to the pKa of the chelating agent contained in the cleaning liquid.

The pH of the cleaning liquid is preferably not less than 7.5 and more preferably not less than 8.0 at 25° C. because this leads to more excellent residue removal performance. The upper limit of the pH of the cleaning liquid is preferably not more than 13.0, more preferably not more than 12.0 and even more preferably not more than 11.5 at 25° C.

The pH of the cleaning liquid may be adjusted by use of a compound selected from the pH adjusters and the anticorrosives having the function of the pH adjuster described above.

The pH of the cleaning liquid can be measured with a known pH meter by the method according to JIS Z 8802-1984.

### [Metal Content]

In the cleaning liquid, the content of each of metals (elemental metals such as Fe, Co, Na, K, Cu, Mg, Mn, Li, Al, Cr, Ni and Zn) contained as impurities in the liquid (calculated as the ion concentration) is preferably not more than 5 ppm by mass and more preferably not more than 1 ppm by mass. Since it is expected in manufacture of leading-edge semiconductor devices that a cleaning liquid with even higher purity should be required, the metal content is still more preferably less than 1 ppm by mass, that is, a value on the order of ppb by mass or less, and particularly preferably 100 ppb by mass or less. The lower limit thereof is not particularly limited and is preferably 0.

Exemplary methods of reducing the metal content include a refining treatment, such as distillation or filtration using ion-exchange resin or a filter, that is carried out in a stage of raw materials to be used in manufacturing the cleaning liquid or a stage after manufacture of the cleaning liquid.

Another method of reducing the metal content is the one using, as a container storing a raw material or the manufactured cleaning liquid, a container from which impurities are not largely leached, which will be described later. Still another method is providing lining of fluororesin on inner walls of pipes used in manufacture of the cleaning liquid in order to prevent metal components from being leached from the pipes.

### [Coarse Particles]

The cleaning liquid may contain coarse particles but preferably in a small amount. The coarse particles herein refer to particles with a diameter (particle size) of 0.4 μm or more when the particle shape is assumed to be a sphere.

For the coarse particle content of the cleaning liquid, the content of particles with a particle size of 0.4 μm or more is preferably not more than 1000 particles and more preferably not more than 500 particles per milliliter of the cleaning liquid. The lower limit thereof is not particularly limited and is preferably 0. The content of particles with a particle size of 0.4 μm or more measured by one of the foregoing measurement methods is preferably at or below the detection limit.

The coarse particles contained in the cleaning liquid are particles of dust, dirt, organic and inorganic solid matter, and the like contained as impurities in raw materials and particles of dust, dirt, organic and inorganic solid matter, and the like entering as contaminations during preparation of the cleaning liquid, which particles remain present as particles in the cleaning liquid at the end without being dissolved.

The content of the coarse particles present in the cleaning liquid can be measured in a liquid phase with a commercial measurement device for a light scattering liquid-borne particle counting method using a laser as a light source.

One exemplary method of removing the coarse particles is a refining treatment such as filtration to be described later.

The cleaning liquid may take the form of a kit including raw materials of the cleaning liquid that are separated into plural units.

One exemplary method of having the cleaning liquid in the form of a kit involves preparing a liquid composition containing the chelating agent as a first liquid and preparing a liquid composition containing the component B as a second liquid.

### [Manufacture of Cleaning Liquid]

The cleaning liquid can be manufactured by a known method. The method of manufacturing the cleaning liquid is described below in detail.

### [Liquid Preparation Step]

The method of preparing the cleaning liquid is not particularly limited, and for instance, the cleaning liquid can be manufactured by mixing the foregoing components. The order and/or timing of incorporating the foregoing components are not particularly limited; for instance, the chelating agent and the component B and/or a given component(s) such as the pH adjuster are sequentially added into a vessel containing purified pure water and then stirred, thereby preparing the cleaning liquid. When added to the vessel, water and components may be added at one time or may be divided into plural portions and separately added.

A stirrer and a stirring method used in preparation of the cleaning liquid are not particularly limited, and a known device may be used as the stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

Mixing of the components in the liquid preparation step of the cleaning liquid, a refining treatment to be described later, and storage of the manufactured cleaning liquid are carried out at a temperature of preferably not higher than 40° C. and more preferably not higher than 30° C. In addition, those processes are carried out at a temperature of preferably not lower than 5° C. and more preferably not lower than 10° C. The cleaning liquid preparation, the treatment and/or the storage within the above temperature ranges makes it possible to maintain stable performance for a long period of time.

### (Refining Treatment)

In manufacture of the kit, it is preferable to previously carry out a refining treatment on one or more of raw materials to be used in preparation of the cleaning liquid. The refining treatment is not particularly limited, and examples thereof include known methods such as distillation, ion exchange, and filtration.

The degree of refining is not particularly limited, and a raw material is refined to a purity of preferably not less than 99 mass % and more preferably not less than 99.9 mass %.

Exemplary methods of the refining treatment include a method in which a raw material is passed through ion-exchange resin, a reverse osmosis membrane (RO membrane), or the like, distillation of a raw material, and filtration to be described later.

As the refining treatment, the foregoing refining methods may be used in combination of two or more. For instance, a raw material may be firstly subjected to primary refinement in which a liquid is passed through a RO membrane and then to secondary refinement in which the liquid is passed through a refinement device made of cation exchange resin, anion exchange resin, or mixed-bed ion exchange resin. The refining treatment may be carried out plural times.

### (Filtration)

A filter used in filtration is not particularly limited as long as it is of a type that has been conventionally used for filtration. Examples of the filter include filters made of fluororesins such as polytetrafluoroethylene (PTFE) and tetrafluoroethylene-perfluoroalkylvinylether copolymer (PFA), polyamide resins such as nylon, and polyolefin resins (including high density ones and ultra high molecular weight ones) such as polyethylene and polypropylene (PP). Preferred is a filter made of, of the above materials, a material selected from the group consisting of polyethylene, polypropylene (including high density polypropylene), fluororesin (including PTFE and PFA), and polyamide resin (including nylon), and more preferred is a filter made of fluororesin. By filtering a raw material with the filter made of such a material, foreign matter with high polarity that easily causes defects can be effectively removed.

The filter has a critical surface tension of preferably 70 to 95 mN/m and more preferably 75 to 85 mN/m. It should be noted that the value of the critical surface tension of the filter is a nominal value provided by its manufacturer. The use of the filter having a critical surface tension within the above ranges makes it possible to effectively remove foreign matter with high polarity that easily causes defects.

The filter has a pore size of preferably 2 to 20 nm and more preferably 2 to 15 nm. The pore size within the above ranges makes it possible to reliably remove fine foreign matter such as impurities and agglomerates contained in a raw material, while preventing clogging in filtration.

Different filters may be combined for filtration. In this case, filtration with a first filter may be carried out only one time or two or more times. When different filters are combined to carry out filtration two or more times, the pore size in the second and subsequent filtrations is preferably equal to or smaller than that in the first filtration. Alternatively, the first filters having different pore sizes within the above ranges may be combined. The pore size herein can be determined by reference to a nominal value of the relevant filter manufacturer.

In terms of commercial products, a filter may be selected from various filters provided by, for example, Nihon Pall Ltd., Advantec Toyo Kaisha, Ltd., Entegris Japan Co., Ltd. (formerly Nippon Microlith Co., Ltd.), and Kitz Microfilter Corporation. Further, “P-Nylon filter (pore size: 0.02 μm, critical surface tension: 77 mN/m)” made of polyamide (manufactured by Nihon Pall Ltd.), “PE-Kleen filter (pore size: 0.02 μm)” made of high-density polyethylene (manufactured by Nihon Pall Ltd.), and “PE-Kleen filter (pore size: 0.01 μm)” made of high-density polyethylene (manufactured by Nihon Pall Ltd.) may also be used.

As a second filter, a filter made of a material same as or similar to that of the first filter may be used. The second filter preferably has a pore size of 1 to 10 nm.

Filtration is carried out preferably at room temperature (25° C.) or lower, more preferably at 23° C. or lower, and even more preferably at 20° C. or lower, and at the same time, preferably at 0° C. or higher, more preferably at 5° C. or higher, and even more preferably at 10° C. or higher. Filtration at a temperature within the foregoing ranges makes it possible to reduce the amounts of particulate foreign matter and impurities dissolved in a raw material and effectively remove foreign matter and impurities.

### <Container>

The cleaning liquid (including an embodiment of a kit or a diluted solution to be described later) can be put into a given container and stored, transported and used as long as problems such as corrosion do not occur.

For the container, preferred is a container which has high cleanliness in its interior and in which leaching of impurities from the inner wall of a storage portion of the container to the liquid is suppressed, for semiconductor applications. Examples of such a container include various containers commercially available as containers for semiconductor cleaning liquids, as exemplified by, but not limited to, the “Clean Bottle” series manufactured by Aicello Corporation and “Pure Bottle” manufactured by Kodama Plastics Co., Ltd.

For the container storing the cleaning liquid, preferred is a container whose portion to contact the liquid, such as the inner wall of its storage portion, is formed from fluororesin (perfluororesin) or metal having undergone a rust proof and metal leaching prevention treatment.

The inner wall of the container is preferably formed from one or more resins selected from the group consisting of polyethylene resin, polypropylene resin, and polyethylene-polypropylene resin, or another resin different therefrom, or a metal having undergone a rust proof and metal leaching prevention treatment such as stainless steel, Hastelloy, Inconel, or Monel.

For another resin above, fluororesin (perfluororesin) is preferred. When such a container with its inner wall being formed from fluororesin is used, defects such as leaching of oligomers of ethylene or propylene can be suppressed as compared to a container with its inner wall being formed from polyethylene resin, polypropylene resin, or polyethylene-polypropylene resin.

Specific examples of such a container with its inner wall being formed from fluororesin include FluoroPure PFA composite drums manufactured by Entegris, Inc. In addition, the containers described in page 4 of JP 3-502677 A, page 3 of WO 2004/016526, pages 9 and 16 of WO 99/46309, and other publications may also be used.

In addition to the foregoing fluororesin, quartz and an electrolytically polished metal material (i.e., a metal material having undergone electrolytic polishing) may also be preferably used for the inner wall of the container.

For a metal material used in manufacture of the foregoing electrolytically polished metal material, preferred is a metal material containing at least one selected from the group consisting of chromium and nickel, with the total content of chromium and nickel being more than 25 mass % based on the total mass of the metal material. Examples of such a metal material include stainless steel and a nickel-chromium alloy.

The total content of chromium and nickel in the metal material is more preferably not less than 30 mass % based on the total mass of the metal material.

The upper limit of the total content of chromium and nickel in the metal material is not particularly limited and is preferably not more than 90 mass %.

The type of the stainless steel is not particularly limited, and any known stainless steels may be used. In particular, an alloy containing not less than 8 mass % of nickel is preferred, and austenitic stainless steel containing not less than 8 mass % of nickel is more preferred. Examples of the austenitic stainless steel include SUS (Steel Use Stainless) 304 (Ni content: 8 mass %, Cr content: 18 mass %), SUS 304L (Ni content: 9 mass %, Cr content: 18 mass %), SUS 316 (Ni content: 10 mass %, Cr content: 16 mass %), and SUS 316L (Ni content: 12 mass %, Cr content: 16 mass %).

The type of the nickel-chromium alloy is not particularly limited, and any known nickel-chromium alloys may be used. In particular, a nickel-chromium alloy with a nickel content of 40 to 75 mass % and a chromium content of 1 to 30 mass % is preferred.

Examples of the nickel-chromium alloy include Hastelloy (commercial name, hereinafter the same), Monel (commercial name, hereinafter the same), and Inconel (commercial name, hereinafter the same), and more specifically, Hastelloy C-276 (Ni content: 63 mass %, Cr content: 16 mass %), Hastelloy-C(Ni content: 60 mass %, Cr content: 17 mass %), and Hastelloy C-22 (Ni content: 61 mass %, Cr content: 22 mass %).

The nickel-chromium alloy may optionally further contain boron, silicon, tungsten, molybdenum, copper, cobalt, and the like in addition to any of the foregoing alloys.

The method of electrolytic polishing of the metal material is not particularly limited, and any known methods may be used. For instance, the methods described in paragraphs [0011] to [0014] of JP 2015-227501 A and paragraphs [0036] to [0042] of JP 2008-264929 A may be used.

In regard to the metal material, probably, electrolytic polishing allows the chromium content of its passive layer at the surface to be higher than that of the matrix. Accordingly, elemental metal does not easily flow out from the inner wall covered with the electrolytically polished metal material into the cleaning liquid. This should probably be the reason why each liquid and the cleaning liquid with reduced amounts of metal impurities can be obtained.

The metal material is preferably subjected to buffing. The method of buffing is not particularly limited, and any known methods may be used. The size of abrasive grains used in buffing finishing is not particularly limited, and the size #400 or a smaller size is preferred because the asperities at a surface of the metal material can be reduced more easily.

Buffing is preferably carried out before electrolytic polishing.

The metal material may be subjected to one or a combination of two or more selected from buffing, pickling, and magnetorheological finishing, the buffing including plural stages carried out with varying grit numbers, e.g., varying sizes of abrasive grains.

Preferably, the inside of the containers is washed before being filled with the cleaning liquid. For a liquid used for washing, the amount of metal impurities in the liquid is preferably reduced. After being manufactured, the cleaning liquid may be bottled in such containers as gallon bottles or quart bottles, and transported or stored.

In order to prevent the components in the cleaning liquid from changing during storage, the inside of each container may be replaced with an inert gas (nitrogen, argon or the like) having a purity of not less than 99.99995 vol in advance. In particular, a gas with a low moisture content is preferred. While the transportation and the storage may be carried out at normal temperature, the temperature may be controlled to fall within the range of −20° C. to 20° C. to prevent the change of properties.

### (Cleanroom)

It is preferable to conduct all of manufacture of the cleaning liquid, opening and washing of the containers, handling of the cleaning liquid such as filling, process and treatment analyses, and measurements in a cleanroom. The cleanroom preferably satisfies 14644-1 cleanroom standards. The cleanroom satisfies preferably one of ISO (International Organization for Standardization) Class 1, ISO Class 2, ISO Class 3, and ISO Class 4, more preferably ISO Class 1 or ISO Class 2, and even more preferably ISO Class 1.

### [Dilution Step]

The cleaning liquid is subjected to a dilution step in which the liquid is diluted with a diluent such as water and then used in cleaning of semiconductor substrates.

In the cleaning liquid of the present invention, when the pKa of the chelating agent and the pH of the cleaning liquid satisfy the relationship of Formula (A) above, a change in the pH caused by dilution conducted for the purpose of use is suppressed. In other words, a difference between the pH of the cleaning liquid that is a concentrated liquid before dilution and the pH of the cleaning liquid having been diluted in the dilution step (hereinafter also referred to as “diluted cleaning liquid”) is small. This contributes to suppression of a variation in residue removal performance that may be caused when the cleaning liquid is diluted for use in cleaning of semiconductor substrates.

The dilution ratio of the cleaning liquid in the dilution step may be adjusted as appropriate depending on the types and contents of the components, the type of semiconductor substrates to be cleaned, and other factors. For the dilution ratio of the cleaning liquid in the dilution step, a ratio of the diluted cleaning liquid to the cleaning liquid before dilution is preferably 10 to 1000 times and more preferably 30 to 300 times in mass ratio.

The cleaning liquid is diluted preferably with water because this leads to more excellent residue removal performance.

As described above, the pH of the diluted cleaning liquid is hardly different from the pH of the cleaning liquid that is a concentrated liquid. A difference between the pH of the cleaning liquid before dilution and the pH of the diluted cleaning liquid is preferably not more than 1.0, more preferably not more than 0.8 and even more preferably not more than 0.5.

The pH of the diluted cleaning liquid is preferably more than 7.0 and more preferably not less than 7.5. The upper limit of the pH of the diluted cleaning liquid is preferably not more than 12.5, more preferably not more than 11.5 and even more preferably not more than 10.5 at 25° C.

A specific method of diluting the cleaning liquid in the dilution step is not particularly limited, and the dilution step may be carried out according to the liquid preparation step of the cleaning liquid described above. A stirrer and a stirring method used in the dilution step are also not particularly limited, and stirring may be carried out with a known stirrer whose examples are listed in the liquid preparation step of the cleaning liquid described above.

Water used in the dilution step is preferably subjected to a refining treatment in advance. Preferably, the diluted cleaning liquid obtained in the dilution step is subjected to a refining treatment.

The refining treatment is not particularly limited, and examples thereof include an ionic component reduction treatment using ion-exchange resin or a RO membrane, and removal of foreign matter through filtration, which are described above as examples of the refining treatment for the cleaning liquid; preferably, one of these treatments is carried out.

The chelating agent content of the diluted cleaning liquid is preferably 0.00001 to 3 mass % and more preferably 0.0001 to 0.3 mass % based on the total mass of the diluted cleaning liquid.

When the diluted cleaning liquid contains the component B, the component B content is preferably 0.000011 to 1.1 mass % and more preferably 0.00011 to 0.11 mass % based on the total mass of the diluted cleaning liquid.

When the diluted cleaning liquid contains the surfactant, the surfactant content is preferably 0.000001 to 0.1 mass % and more preferably 0.00001 to 0.01 mass % based on the total mass of the diluted cleaning liquid.

When the diluted cleaning liquid contains the anticorrosive, the anticorrosive content is preferably 0.00001 to 1 mass % and more preferably 0.0001 to 0.1 mass % based on the total mass of the diluted cleaning liquid.

It is also preferable that, after the liquid preparation step as above, the cleaning liquid is subjected to a concentration step to prepare a concentrated liquid through concentration and then to the dilution step as above.

The method of concentrating the cleaning liquid in the concentration step is not particularly limited as long as the performance of the cleaning liquid is not impaired, and concentration can be carried out by a known method such as distillation.

The concentration ratio of the cleaning liquid in the concentration step may be suitably adjusted depending on, for instance, the types and the contents of the components, and a ratio of the concentrated liquid to the cleaning liquid before concentration is preferably 1/50 to 1/5000 times and more preferably 1/100 to 1/3000 times in mass ratio.

In particular, when the ratio of the concentrated liquid to the cleaning liquid before concentration is high, the decomposition of compounds may be accelerated. For the cleaning liquid, concentration is preferably carried out at a ratio within the foregoing ranges because the decomposition of compounds can be suppressed even with a high concentration ratio and also because of easy transportation and the like.

### [Application of Cleaning Liquid]

The cleaning liquid is usable in any step in a semiconductor substrate manufacturing process as long as it is used for cleaning semiconductor substrates. The cleaning liquid is preferably used in cleaning of semiconductor substrates having undergone a chemical mechanical polishing (CMP) process.

Note that the diluted cleaning liquid obtained by diluting the cleaning liquid is used in actual cleaning of semiconductor substrates, as described above.

### [Semiconductor Substrate]

A semiconductor substrate to be cleaned with the cleaning liquid is not particularly limited, and examples thereof include one having a metal wiring film, a barrier metal, and an insulating film on a surface of a wafer constituting the semiconductor substrate.

Specific examples of the wafer constituting the semiconductor substrate include wafers made of silicon-based materials such as a silicon (Si) wafer, a silicon carbide (SiC) wafer, and a silicon-containing resin wafer (glass epoxy wafer), a gallium phosphide (GaP) wafer, a gallium arsenide (GaAs) wafer, and an indium phosphide (InP) wafer.

Applicable examples of the silicon wafer include an n-type silicon wafer in which a silicon wafer is doped with a pentavalent atom (e.g., phosphorus (P), arsenic (As), and antimony (Sb)), and a p-type silicon wafer in which a silicon wafer is doped with a trivalent atom (e.g., boron (B), and gallium (Ga)). Silicon of the silicon wafer may be any of, for example, amorphous silicon, monocrystalline silicon, polycrystalline silicon, and polysilicon.

In particular, the cleaning liquid is useful for wafers made of silicon-based materials such as a silicon wafer, a silicon carbide wafer, and a silicon-containing resin wafer (glass epoxy wafer).

The semiconductor substrate may have an insulating film on the wafer described above.

Specific examples of the insulating film include silicon oxide films (e.g., a silicon dioxide (SiO₂) film and a tetraethyl orthosilicate (Si(OC₂H₅)₄) film (TEOS film)), silicon nitride films (e.g., silicon nitride (Si₃N₄) and silicon nitride/carbide (SiNC)), and low dielectric (Low-k) films (e.g., a carbon-doped silicon oxide (SiOC) film and a silicon carbide (SiC) film).

Examples of a metal film that the semiconductor substrate has on a surface of the wafer include a film primarily composed of copper (Cu) (copper-containing film), a film primarily composed of cobalt (Co) (cobalt-containing film), a film primarily composed of tungsten (W) (tungsten-containing film), and a metal film constituted of an alloy including one or more selected from the group consisting of Cu, Co and W.

Examples of the copper-containing film include a wiring film composed only of metallic copper (copper wiring film) and a wiring film made of an alloy composed of metallic copper and other metals (copper alloy wiring film).

Specific examples of the copper alloy wiring film include a wiring film made of an alloy composed of copper and one or more metals selected from aluminum (Al), titanium (Ti), chromium (Cr), manganese (Mn), tantalum (Ta) and tungsten (W). More specifically, examples thereof include a copper-aluminum alloy wiring film (CuAl alloy wiring film), a copper-titanium alloy wiring film (CuTi alloy wiring film), a copper-chromium alloy wiring film (CuCr alloy wiring film), a copper-manganese alloy wiring film (CuMn alloy wiring film), a copper-tantalum alloy wiring film (CuTa alloy wiring film), and a copper-tungsten alloy wiring film (CuW alloy wiring film).

Examples of the cobalt-containing film (a metal film primarily composed of cobalt) include a metal film composed only of metallic cobalt (cobalt metal film) and a metal film made of an alloy composed of metallic cobalt and other metals (cobalt alloy metal film).

Specific examples of the cobalt alloy metal film include a metal film made of an alloy composed of cobalt and one or more metals selected from titanium (Ti), chromium (Cr), iron (Fe), nickel (Ni), molybdenum (Mo), palladium (Pd), tantalum (Ta) and tungsten (W). More specifically, examples thereof include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt-tantalum alloy metal film (CoTa alloy metal film), and a cobalt-tungsten alloy metal film (CoW alloy metal film).

The cleaning liquid is useful for the substrate having the cobalt-containing film. Of the cobalt-containing films, the cobalt metal film is often used as a wiring film, and the cobalt alloy metal film is often used as a barrier metal.

In some cases, it is preferable to use the cleaning liquid in cleaning of the semiconductor substrate having at least the copper-containing wiring film and the metal film (cobalt barrier metal), which is composed only of metallic cobalt and is a barrier metal of the copper-containing wiring film, on or above the wafer constituting the substrate, with the copper-containing wiring film and the cobalt barrier metal being in contact with each other at a surface of the substrate.

Examples of the tungsten-containing film (a metal film primarily composed of tungsten) include a metal film composed only of metallic tungsten (tungsten metal film) and a metal film made of an alloy composed of tungsten and other metals (tungsten alloy metal film).

Specific examples of the tungsten alloy metal film include a tungsten-titanium alloy metal film (WTi alloy metal film) and a tungsten-cobalt alloy metal film (WCo alloy metal film).

The tungsten-containing film is often used as a barrier metal.

The method of forming the foregoing insulating film, copper-containing wiring film, cobalt-containing film and tungsten-containing film on the wafer constituting the semiconductor substrate is not particularly limited as long as it is a known method used in this field.

One exemplary method of forming the insulating film is a method in which the wafer constituting the semiconductor substrate is subjected to a heating treatment in the presence of oxygen gas to form a silicon oxide film, whereafter silane and ammonia gases are introduced to form a silicon nitride film by a chemical vapor deposition (CVD) method.

Exemplary methods of forming the copper-containing wiring film, the cobalt-containing film and the tungsten-containing film include a method in which a circuit is formed on the wafer having the above insulating film by a known method using a resist for instance, whereafter the copper-containing wiring film, the cobalt-containing film and the tungsten-containing film are formed by plating, the CVD method, or another process.

### (CMP Process)

The CMP process is, for instance, a process for planarizing a surface of the substrate having the metal wiring film, the barrier metal and the insulating film through a combination of a chemical action induced by use of a polishing slurry containing fine abrasive particles (abrasive grains) and mechanical polishing. Abrasive grains (e.g., silica and alumina) used in the CMP process, metal impurities (metal residues) derived from the polished metal wiring film and barrier metal, and other impurities sometimes remain on the surface of the semiconductor substrate having undergone the CMP process.

These impurities may cause short circuit between wirings and adversely affect electric characteristics of the semiconductor substrate; therefore, the semiconductor substrate having undergone the CMP process is subjected to a cleaning treatment to remove these impurities from the surface of the semiconductor substrate.

One specific example of the semiconductor substrate having undergone the CMP process is not limited to but includes a substrate having undergone the CMP process described in Journal of the Japan Society for Precision Engineering, Vol. 84, No. 3, 2018.

### [Method of Cleaning Semiconductor Substrate]

The method of cleaning the semiconductor substrate is not particularly limited as long as it is a method in which a surface of the semiconductor substrate is brought into contact with the cleaning liquid (diluted cleaning liquid).

One exemplary method of cleaning the semiconductor substrate is a method in which the semiconductor substrate is immersed in the diluted cleaning liquid obtained in the dilution step described above, thereby cleaning the semiconductor substrate. In this process, an ultrasonic treatment is preferably carried out on the cleaning liquid having the semiconductor substrate immersed therein because this can further reduce impurities remaining on the surface of the semiconductor substrate.

The method of cleaning is not limited to immersion, and there may be suitably employed any known method in this field such as a spinning (dropping) method in which the cleaning liquid is dropped while the semiconductor substrate is rotated, or a spraying method in which the cleaning liquid is sprayed.

The method of cleaning the semiconductor substrate to be employed may be any of a single wafer process and a batch process. The single wafer process is a method in which semiconductor substrates are treated one by one, while the batch process is a method in which a plurality of semiconductor substrates are treated at one time.

The temperature of the cleaning liquid used in cleaning of the semiconductor substrate is not particularly limited as long as it is the temperature of the cleaning liquid used in cleaning in this field. While the cleaning liquid at room temperature (25° C.) is often used, the upper limit of the temperature can be arbitrarily selected to improve cleaning properties and/or reduce damage to a member; for instance, the cleaning liquid has a temperature of preferably 10° C. to 60° C. and more preferably 15° C. to 50° C.

The cleaning time in cleaning of the semiconductor substrate depends on, for example, the types and the contents of components in the cleaning liquid and therefore cannot be unconditionally stated; practically, the cleaning time is preferably 10 seconds to 2 minutes, more preferably 20 seconds to 1 minute and 30 seconds, and even more preferably 30 seconds to 1 minute.

In cleaning of the semiconductor substrate, a mechanical stirring method may be used to further enhance the cleaning ability of the cleaning liquid.

Examples of the mechanical stirring method include a method involving circulating the cleaning liquid on the semiconductor substrate, a method involving flowing or spraying the cleaning liquid on the semiconductor substrate, and a method involving stirring the cleaning liquid by ultrasonics or megasonics.

The cleaning of the semiconductor substrate may be followed by a step of rinsing and washing the semiconductor substrate with a solvent (hereinafter called “rinsing step”).

The rinsing step is preferably a step that consecutively follows the cleaning step of the semiconductor substrate and that is carried out with a rinsing solvent (rinsing liquid) for 5 seconds to 5 minutes. The rinsing step may be carried out using the mechanical stirring method as above.

Examples of the rinsing solvent include deionized (DI) water, methanol, ethanol, isopropyl alcohol, N-methylpyrrolidinone, γ-butyrolactone, dimethyl sulfoxide, ethyl lactate, and propylene glycol monomethyl ether acetate. Alternatively, an aqueous rinsing liquid with a pH of more than 8 (e.g., a diluted aqueous ammonium hydroxide) may be used.

The forgoing method of bringing the cleaning liquid into contact with the semiconductor substrate is applicable as the method of bringing the rinsing solvent into contact with the semiconductor substrate in the same manner.

The rinsing step may be followed by a drying step for drying the semiconductor substrate.

The drying method is not particularly limited, and examples thereof include spin drying, a method involving flowing dry gas on the semiconductor substrate, a method involving heating the substrate by a heating means such as a hot plate or an infrared lamp, Marangoni drying, Rotagoni drying, isopropyl alcohol (IPA) drying, and any combinations thereof.

### Examples

The present invention is described below in further detail based on examples. The materials, amounts of use, and ratios illustrated in examples below may be suitably modified as long as they do not depart from the scope and spirit of the present invention. Therefore, the scope of the present invention should not be construed as being limited to the examples below.

In the examples below, the pH values of cleaning liquids and diluted cleaning liquids were measured with a pH meter (type: F-74, manufactured by HORIBA, Ltd.) according to JIS Z 8802-1984.

In manufacture of cleaning liquids of Examples and Comparative Examples, handling of containers and preparation, filling, storage, analysis and measurement of the cleaning liquids were all conducted in a cleanroom with the level satisfying ISO Class 2 or lower class. In measurement of the metal content of a cleaning liquid, when the content of a substance at or below the detection limit was measured, the measurement was carried out after the cleaning liquid was concentrated to 1/100 in terms of volume, and the measurement result was converted into a value of the metal content of the liquid at the concentration before the liquid was concentrated, in order to improve the measurement accuracy.

### [Composition of Cleaning Liquid]

The following compounds were used as chelating agents in manufacture of cleaning liquids. In addition, the acidity constant (pKa) of each chelating agent is shown in Table 1.
Citric acid: manufactured by Fuso Chemical Co., Ltd.
1-Hydroxyethylidene-1,1′-diphosphonic acid (HEDP): “Dequest 2000” manufactured by Thermphos
Arginine (L-arginine): manufactured by Tokyo Chemical Industry Co., Ltd.
Tartaric acid: manufactured by FUJIFILM Wako Pure Chemical Corporation
N,N,N′,N′-Ethylenediaminetetrakis(methylenephosphonic acid) (EDTPO): “Dequest 2066” manufactured by Thermphos
Diethylenetriaminepentaacetic acid (DTPA): manufactured by FUJIFILM Wako Pure Chemical Corporation
Ethylenediaminetetraacetic acid (EDTA): manufactured by Chelest Corporation
Glycine (Gly): manufactured by FUJIFILM Wako Pure Chemical Corporation
β-Alanine (ALA): manufactured by FUJIFILM Wako Pure Chemical Corporation

TABLE 1

| | pKa | | | | | | | |
|---|---|---|---|---|---|---|---|---|
| Table 1 | pKa1 | pKa2 | pKa3 | pKa4 | pKa5 | pKa6 | pKa7 | pKa8 |
| Citric acid | 3.09 | 4.75 | 6.71 | — | — | — | — | — |
| HEDP | 1.35 | 2.87 | 7.03 | 11.3 | — | — | — | — |
| Arginine | 1.82 | 9.01 | 12.48 | — | — | — | — | — |
| Tartaric acid | 4.30 | 7.40 | — | — | — | — | — | — |
| EDTPO | 1.46 | 2.72 | 5.06 | 6.18 | 6.63 | 7.43 | 9.22 | 10.6 |
| DTPA | 2.14 | 2.38 | 4.26 | 8.60 | 10.53 | — | — | — |
| EDTA | 2.00 | 2.70 | 6.2 | 10.30 | — | — | — | — |
| Gly | 2.35 | 9.78 | — | — | — | — | — | — |
| ALA | 2.35 | 9.87 | — | — | — | — | — | — |

The following compounds were used as surfactants (components B) in manufacture of cleaning liquids.
Lauryl phosphoric acid (lauryl phosphoric acid ester): anionic surfactant, “Phosten HLP” manufactured by Nikko Chemicals Co., Ltd.
Dodecylbenzenesulfonic acid (DBSA): anionic surfactant, manufactured by FUJIFILM Wako Pure Chemical Corporation
Dinitrobenzenesulfonic acid (DNBSA): anionic surfactant, manufactured by KAO Corporation
Lauryl diphenyl ether disulfonic acid (LDPEDSA): anionic surfactant, “TAKESURF A-43-N” manufactured by Takemoto Oil & Fat Co., Ltd.
Polyoxyethylene dioleate (POED): nonionic surfactant, “NEW KALGEN D-2504-D” manufactured by Takemoto Oil & Fat Co., Ltd.
Polyoxyethylene lauryl ether phosphoric acid ester (POE lauryl phosphoric acid): anionic surfactant, manufactured by Nikko Chemicals Co., Ltd.

The following compounds were used as anticorrosives (components B) in manufacture of cleaning liquids.
Diazabicycloundecene (DBU): manufactured by FUJIFILM Wako Pure Chemical Corporation
Piperazine: manufactured by FUJIFILM Wako Pure Chemical Corporation
Diethylhydroxylamine (DEHA): manufactured by FUJIFILM Wako Pure Chemical Corporation
Diazabicyclononene (DEN): manufactured by FUJIFILM Wako Pure Chemical Corporation
5-Aminotetrazole: manufactured by FUJIFILM Wako Pure Chemical Corporation
1H-Tetrazole: manufactured by FUJIFILM Wako Pure Chemical Corporation
1,2,4-Triazole: manufactured by FUJIFILM Wako Pure Chemical Corporation
2-Aminopyrimidine: manufactured by FUJIFILM Wako Pure Chemical Corporation
Ascorbic acid: manufactured by FUJIFILM Wako Pure Chemical Corporation
Gallic acid: manufactured by FUJIFILM Wako Pure Chemical Corporation
1,4-Bis(3-aminopropyl)piperazine (BAP): manufactured by FUJIFILM Wako Pure Chemical Corporation
1-(2-Hydroxyethyl)piperazine (REP): manufactured by FUJIFILM Wako Pure Chemical Corporation
1,3-Diaminopropane: manufactured by FUJIFILM Wako Pure Chemical Corporation (this compound does not fall under the component B)

The following compounds were used as pH adjusters in manufacture of cleaning liquids.
Ammonia water (NH₃): manufactured by FUJIFILM Wako Pure Chemical Corporation
2-Hydroxyethyl trimethylammonium hydroxide (choline): manufactured by FUJIFILM Wako Pure Chemical Corporation
Tetrabutylammonium hydroxide (TBAH): manufactured by FUJIFILM Wako Pure Chemical Corporation
2-Amino-2-methyl-1-propanol (AMP): manufactured by FUJIFILM Wako Pure Chemical Corporation
Monoethanolamine (MEA): manufactured by FUJIFILM Wako Pure Chemical Corporation
Diethanolamine (DEA): manufactured by FUJIFILM Wako Pure Chemical Corporation
Tris(hydroxymethyl)aminomethane (Tris): manufactured by FUJIFILM Wako Pure Chemical Corporation
Dimethylbis(2-hydroxyethyl)ammonium hydroxide (A14212): manufactured by FUJIFILM Wako Pure Chemical Corporation
2-(2-Aminoethoxy)ethanol (AEE): manufactured by FUJIFILM Wako Pure Chemical Corporation
4-(2-Aminoethyl)morpholine (AEM): manufactured by FUJIFILM Wako Pure Chemical Corporation

In addition, commercial ultrapure water (manufactured by FUJIFILM Wako Pure Chemical Corporation) was used in manufacture of cleaning liquids in Examples and in the dilution step of the cleaning liquids.

### [Manufacture of Cleaning Liquid]

A method of manufacturing a cleaning liquid is described taking Example 1 as an example.

Citric acid and HEDP were used as the chelating agents, and DBU was used as the anticorrosive of the component B. Citric acid and HEDP were added to ultrapure water in such amounts as stated in Table 2-1, and then DBU was added such that the pH of a resulting cleaning liquid was to be 8.0. The resulting mixture was sufficiently stirred with a stirrer, thereby obtaining a cleaning liquid of Example 1.

Cleaning liquids of Examples 2 to 103 and Comparative Examples 1 to 4 with the compositions shown in Tables 2-1 to 2-4 were manufactured according to the manufacturing method of Example 1.

In each cleaning liquid, the remainder other than those components shown in Tables 2-1 to 2-4 was water.

The “Amount” columns in Tables 2-1 to 2-4 provide the amounts of the respective components contained based on the total mass of the relevant cleaning liquid.

The notation “*1” in the “Amount” columns means that the amount of the relevant compound was adjusted such that the pH of the resulting cleaning liquid was to be a value stated in the relevant “pH” field in Tables 2-1 to 2-4.

In Tables 2-1 to 2-4, the values in the “Ratio” columns of the “Chelating agent” sections each represent a mass ratio of the content of one chelating agent to the content of the other chelating agent in cases where plural chelating agents were used.

### [Measurement of Metal Content]

The metal contents of the cleaning liquids manufactured in Examples and Comparative Examples were measured.

The metal contents were measured with Agilent 8800 triple quadrupole ICP-MS (for semiconductor analysis, option #200) under the following measurement conditions.

### (Measurement Conditions)

For a sample introduction system, a PFA nebulizer (for self-suction) of the type coaxial with a quartz torch, and a platinum interface cone were used. Measurement parameters for the cool plasma condition were as follows.
Radio frequency (RF) output (W): 600
Flow rate of carrier gas (L/min): 0.7
Flow rate of make-up gas (L/min): 1
Sampling depth (mm): 18

In measurement of the metal content, metal particles and metal ions were not distinguished from each other, and the total content thereof was obtained. When two or more metals were detected, the total content of the two or more metals was obtained.

The measurement results of the metal contents are shown in the “metal content” columns of Tables 2 (unit: ppb by mass). In Tables 2, the notations “<10,” “<0.1,” and “>100000” represent the metal contents of the relevant cleaning liquid of less than 10 ppb by mass, less than 0.1 ppb by mass, and more than 100000 ppb by mass (more than 100 ppm by mass) based on the total mass of the cleaning liquid, respectively.

### [Evaluation of Change in pH Caused by Dilution]

The cleaning liquids manufactured by the foregoing method were evaluated for the performance in suppressing a change in the pH caused by dilution.

One milliliter of the cleaning liquid of each of Examples and Comparative Examples was taken and diluted 100 times in volume ratio with ultrapure water to prepare a sample of the diluted cleaning liquid, and the pH of the obtained sample was measured. From the measurement result, a difference (absolute value) between the pH of the cleaning liquid before dilution and the pH of the cleaning liquid after dilution (diluted cleaning liquid) was calculated. Based on the calculation result thus obtained, each cleaning liquid was evaluated for the performance in suppressing a change in the pH caused by dilution according to the following evaluation criteria. The results are shown in Tables 2.

“A”: A difference between pH values before and after dilution being less than 1.0

“B”: A difference between pH values before and after dilution being not less than 1.0 and less than 1.5

“C”: A difference between pH values before and after dilution being not less than 1.5 and less than 2.0

“D”: A difference between pH values before and after dilution being not less than 2.0

### [Evaluation of Defect Suppression Performance]

The cleaning liquids manufactured by the foregoing method were evaluated for the defect suppression performance in the case where a polished metal film was cleaned.

One milliliter of the cleaning liquid of each of Examples and Comparative Examples was taken and diluted 100 times in volume ratio with ultrapure water to prepare a sample of the diluted cleaning liquid.

A wafer (diameter: 12 inches) having on its surface a film made of copper, cobalt or tungsten was polished with FREX 300S-II (a polishing apparatus, manufactured by Ebara Corporation) under the conditions of a polishing pressure of 2.0 psi and a polishing slurry feed rate of 0.28 ml/(min·cm²). As the polishing slurry, CSL5220C (commercial name, manufactured by FUJIFILM Planar Solutions LLC.) was used for a wafer having a Co-containing film, BSL8120C (commercial name, manufactured by FUJIFILM Planar Solutions LLC.) for a wafer having a Cu-containing film, and W2000 (commercial name, manufactured by Cabot Corporation) for a wafer having a W-containing film. The polishing time was 60 seconds.

Thereafter, scrub cleaning was carried out for 60 minutes by use of the sample of each diluted cleaning liquid whose temperature was adjusted to room temperature (23° C.), followed by drying. The number of defects at a polished surface of the obtained wafer was detected with a defect detection apparatus (ComPlus II, manufactured by Applied Materials, Inc.), and the cleaning liquid was evaluated for the defect suppression performance according to the following evaluation criteria. The results are shown in Tables 2.

“A”: The number of defects being not more than 500

“B”: The number of defects being more than 500 and not more than 1000

“C”: The number of defects being more than 1000 and not more than 1500

“D”: The number of defects being more than 1500

### [Evaluation of Storage Stability]

The cleaning liquids manufactured by the foregoing method were evaluated for the storage stability.

A container for semiconductor cleaning liquids was filled with the cleaning liquid of each of Examples 1 to 103 and Comparative Examples 1 to 4 manufactured according to the foregoing method. Each container storing the cleaning liquid was placed in a constant temperature tank with a temperature of 30° C. and a humidity of 50% RH and retained in the constant temperature tank for 1 year.

The number of defects at a polished surface of the obtained wafer was detected in the same manner as the evaluation method for the defect suppression performance described above except that use was made of a sample of the diluted cleaning liquid prepared by taking 1 mL of the cleaning liquid of each of Examples and Comparative Examples having undergone the storage test and diluting the taken liquid 100 times in volume ratio with ultrapure water, and the cleaning liquid was evaluated for the storage stability according to the following evaluation criteria. The results are shown in Tables 2.

“A”: The number of defects being not more than 500

“B”: The number of defects being more than 500 and not more than 1000

“C1”: The number of defects being more than 1000 and not more than 1250

“C2”: The number of defects being more than 1250 and not more than 1500

“D”: The number of defects being more than 1500

TABLE 2
Composition of cleaning liquid

| | | | | | | Component B | | | | | |
|---|---|---|---|---|---|---|---|---|---|---|---|
| | Chelating agent | | | | | Surfactant | | Anticorrosive | | | |
| | | Amount | | Amount | | | Amount | | Amount | | Amount |
| Table 2-1 | Type | (%) | Type | (%) | Ratio | Type | (%) | Type | (%) | Type | (%) |
| EX 1 | Citric acid | 7.5 | HEDP | 0.04 | 187.5 | — | — | DBU | *1 | — | — |
| EX 2 | Citric acid | 7.5 | HEDP | 0.04 | 187.5 | — | — | — | — | — | — |
| EX 3 | Citric acid | 7.5 | HEDP | 0.04 | 187.5 | — | — | — | — | — | — |
| EX 4 | Citric acid | 7.5 | HEDP | 0.04 | 187.5 | — | — | DBU | *1 | — | — |
| EX 5 | Arginine | 0.3 | HEDP | 0.04 | 7.5 | — | — | DBU | *1 | — | — |
| EX 6 | Arginine | 0.3 | HEDP | 0.04 | 7.5 | — | — | DBU | *1 | — | — |
| EX 7 | Arginine | 0.3 | HEDP | 0.04 | 7.5 | — | — | DBU | *1 | — | — |
| EX 8 | Arginine | 0.3 | Tartaric acid | 1.9 | 6.3 | — | — | Piperazine | 0.1 | DEHA | 4.5 |
| EX 9 | EDTPO | 0.2 | HEDP | 0.04 | 5.0 | — | — | DBU | *1 | — | — |
| EX 10 | EDTPO | 0.2 | HEDP | 0.04 | 5.0 | — | — | DBU | *1 | — | — |
| EX 11 | EDTPO | 0.2 | HEDP | 0.04 | 5.0 | — | — | DBN | *1 | — | — |
| EX 12 | EDTPO | 0.2 | HEDP | 0.04 | 5.0 | — | — | DBU | *1 | — | — |
| EX 13 | EDTPO | 0.2 | Citric acid | 7.5 | 37.5 | — | — | DBU | *1 | — | — |
| EX 14 | EDTPO | 0.2 | Citric acid | 7.5 | 37.5 | — | — | — | — | — | — |
| EX 15 | DTPA | 10 | HEDP | 0.04 | 250.0 | — | — | DBU | *1 | — | — |
| EX 16 | DTPA | 10 | HEDP | 0.04 | 250.0 | — | — | DBU | *1 | — | — |
| EX 17 | DTPA | 2.0 | Citric acid | 7.5 | 3.8 | — | — | DBU | *1 | — | — |
| EX 18 | EDTPO | 0.2 | Citric acid | 7.5 | 37.5 | — | — | — | — | — | — |
| EX 19 | EDTPO | 0.2 | Citric acid | 7.5 | 37.5 | — | — | — | — | — | — |
| EX 20 | DTPA | 10 | HEDP | 0.04 | 250.0 | — | — | DEHA | 4.5 | — | — |
| EX 21 | DTPA | 10 | HEDP | 0.04 | 250.0 | — | — | — | — | — | — |
| EX 22 | DTPA | 2.0 | Citric acid | 7.5 | 3.8 | — | — | — | — | — | — |
| EX 23 | DTPA | 2.0 | Citric acid | 7.5 | 3.8 | — | — | DBU | *1 | — | — |
| EX 24 | DTPA | 2.0 | Citric acid | 7.5 | 3.8 | — | — | DBU | *1 | — | — |
| EX 25 | DTPA | 2.0 | Citric acid | 7.5 | 3.8 | — | — | DBN | *1 | — | — |
| EX 26 | HEDP | 0.04 | — | — | — | — | — | DBU | *1 | — | — |
| EX 27 | HEDP | 0.04 | — | — | — | — | — | DBU | *1 | — | — |
| EX 28 | HEDP | 0.04 | — | — | — | — | — | DEHA | 4.5 | — | — |
| EX 29 | HEDP | 0.04 | — | — | — | — | — | — | — | — | — |
| EX 30 | Citric acid | 7.5 | HEDP | 0.04 | 187.5 | Lauryl | 0.03 | DBU | *1 | — | — |
| | | | | | | phosphoric acid | | | | | |

EX: Example

TABLE 3
Composition of cleaning liquid

| | | | | | | | | | | | Defect suppression | | |
|---|---|---|---|---|---|---|---|---|---|---|---|---|---|
| | | | | | | | | Defect suppression | | | performance (after | | |
| | Component B | | pH | | | Metal | pH | performance | | | storage test) | | |
| Table 2-1 | Anticorrosive | | adjuster | | | content | change | Object of Polishing | | | Object of Polishing | | |
| (continuation) | Type | Amount (%) | Type | Amount (%) | pH | (ppb) | evaluation | Cu | W | Co | Cu | W | Co |
| EX 1 | — | — | — | — | 8.0 | <10 | A | B | A | B | C1 | B | C1 |
| EX 2 | — | — | NH₃ | *1 | 8.0 | <10 | A | C | B | B | C2 | C1 | C1 |
| EX 3 | — | — | Choline | *1 | 8.0 | <10 | A | C | B | B | C1 | B | B |
| EX 4 | — | — | — | — | 10.5 | <10 | A | B | A | B | C1 | B | C1 |
| EX 5 | — | — | — | — | 9.0 | <10 | A | B | A | B | C1 | B | C1 |
| EX 6 | — | — | — | — | 10.0 | <10 | A | B | A | B | C1 | B | C1 |
| EX 7 | — | — | — | — | 11.0 | <10 | A | B | A | B | C1 | B | C1 |
| EX 8 | DBU | *1 | — | — | 10.0 | <10 | A | B | A | B | C1 | Cl | C1 |
| EX 9 | — | — | — | — | 8.0 | <10 | A | B | A | B | C1 | B | C1 |
| EX 10 | — | — | — | — | 9.0 | <10 | A | B | A | B | C1 | B | C1 |
| EX 11 | — | — | — | — | 10.0 | <10 | A | B | A | B | C1 | B | C1 |
| EX 12 | — | — | — | — | 10.5 | <10 | A | B | A | B | C1 | B | C1 |
| EX 13 | — | — | — | — | 8.0 | <10 | A | B | A | B | C1 | B | C1 |
| EX 14 | — | — | TBAH | *1 | 9.0 | <10 | A | B | B | B | B | B | B |
| EX 15 | — | — | — | — | 9.0 | <10 | A | B | A | B | C1 | B | C1 |
| EX 16 | — | — | — | — | 10.0 | <10 | A | B | A | B | C1 | B | C1 |
| EX 17 | — | — | — | — | 9.0 | <10 | A | B | A | B | C1 | B | C1 |
| EX 18 | — | — | AMP | 6.0 | 8.0 | <10 | A | B | A | B | B | A | B |
| EX 19 | — | — | AMP | 6.0 | 9.0 | <10 | A | B | A | B | B | A | B |
| | | | TBAH | *1 | | | | | | | | | |
| EX 20 | — | — | AMP | 6.0 | 9.0 | <10 | A | B | A | B | B | B | B |
| EX 21 | — | — | AMP | 6.0 | 10.0 | <10 | A | B | A | B | B | A | B |
| EX 22 | — | — | AMP | 6.0 | 9.0 | <10 | A | B | A | B | B | A | B |
| EX 23 | — | — | — | — | 10.0 | <10 | A | B | A | B | C1 | B | C1 |
| EX 24 | — | — | — | — | 8.0 | <10 | A | B | A | B | C1 | B | C1 |
| EX 25 | — | — | — | — | 10.5 | <10 | A | B | A | B | C1 | B | C1 |
| EX 26 | — | — | — | — | 8.0 | <10 | A | B | A | B | C1 | B | C1 |
| EX 27 | — | — | — | — | 10.5 | <10 | A | B | A | B | C1 | B | C1 |
| EX 28 | — | — | AMP | 12.0 | 10.5 | <10 | A | B | A | B | B | B | B |
| EX 29 | — | — | AMP | 1.0 | 10.0 | <10 | A | B | A | B | B | A | B |
| EX 30 | — | — | — | — | 8.0 | <10 | A | A | A | A | B | B | B |

EX: Example

TABLE 4
Composition of cleaning liquid

| | | | | | | Component B | | | | | |
|---|---|---|---|---|---|---|---|---|---|---|---|
| | Chelating agent | | | | | Surfactant | | Anticorrosive | | | |
| Table 2-2 | Type | Amount (%) | Type | Amount (%) | Ratio | Type | Amount (%) | Type | Amount (%) | Type | Amount (%) |
| EX 31 | Citric acid | 7.5 | HEDP | 0.04 | 187.5 | Lauryl | 0.03 | — | — | — | — |
| | | | | | | phosphoric acid | | | | | |
| EX 32 | Citric acid | 7.5 | HEDP | 0.04 | 187.5 | Lauryl | 0.03 | — | — | — | — |
| | | | | | | phosphoric acid | | | | | |
| EX 33 | Citric acid | 7.5 | HEDP | 0.04 | 187.5 | Lauryl | 0.03 | DBU | *1 | — | — |
| | | | | | | phosphoric acid | | | | | |
| EX 34 | HEDP | 0.04 | — | — | — | Lauryl | 0.03 | DEHA | 4.5 | — | — |
| | | | | | | phosphoric acid | | | | | |
| EX 35 | Arginine | 0.3 | HEDP | 0.04 | 7.5 | Lauryl | 0.03 | — | — | — | — |
| | | | | | | phosphoric acid | | | | | |
| EX 36 | Arginine | 0.3 | HEDP | 0.04 | 7.5 | Lauryl | 0.03 | DBU | *1 | — | — |
| | | | | | | phosphoric acid | | | | | |
| EX 37 | Arginine | 0.3 | HEDP | 0.04 | 7.5 | Lauryl | 0.03 | DBU | *1 | — | — |
| | | | | | | phosphoric acid | | | | | |
| EX 38 | EDTPO | 0.2 | HEDP | 0.04 | 5.0 | Lauryl | 0.03 | DBU | *1 | — | — |
| | | | | | | phosphoric acid | | | | | |
| EX 39 | EDTPO | 0.2 | HEDP | 0.04 | 5.0 | Lauryl | 0.03 | DBU | *1 | — | — |
| | | | | | | phosphoric acid | | | | | |
| EX 40 | EDTPO | 0.2 | HEDP | 0.04 | 5.0 | Lauryl | 0.03 | DBN | *1 | — | — |
| | | | | | | phosphoric acid | | | | | |
| EX 41 | EDTPO | 0.2 | HEDP | 0.04 | 5.0 | Lauryl | 0.03 | DBU | *1 | — | — |
| | | | | | | phosphoric acid | | | | | |
| EX 42 | EDTPO | 0.2 | Citric acid | 7.5 | 37.5 | Lauryl | 0.03 | DBU | *1 | — | — |
| | | | | | | phosphoric acid | | | | | |
| EX 43 | EDTPO | 0.2 | Citric acid | 7.5 | 37.5 | Lauryl | 0.03 | — | — | — | — |
| | | | | | | phosphoric acid | | | | | |
| EX 44 | DTPA | 10.0 | HEDP | 0.04 | 250.0 | Lauryl | 0.03 | DBU | *1 | — | — |
| | | | | | | phosphoric acid | | | | | |
| EX 45 | DTPA | 10.0 | HEDP | 0.04 | 250.0 | Lauryl | 0.03 | DBU | *1 | — | — |
| | | | | | | phosphoric acid | | | | | |
| EX 46 | DTPA | 2.0 | Citric acid | 7.5 | 3.8 | Lauryl | 0.03 | DBU | *1 | — | — |
| | | | | | | phosphoric acid | | | | | |
| EX 47 | DTPA | 2.0 | Citric acid | 7.5 | 3.8 | Lauryl | 0.03 | DBU | *1 | — | — |
| | | | | | | phosphoric acid | | | | | |
| EX 48 | DTPA | 0.1 | — | — | — | DBSA | 0.03 | — | — | — | — |
| EX 49 | DTPA | 0.1 | — | — | — | LDPEDSA | 0.03 | — | — | — | — |
| EX 50 | DTPA | 0.1 | — | — | — | LDPEDSA | 0.03 | DENA | 4.5 | — | — |
| EX 51 | DTPA | 2.0 | Citric acid | 7.5 | 3.8 | DBSA | 0.03 | DBU | *1 | — | — |
| EX 52 | DTPA | 2.0 | Citric acid | 7.5 | 3.8 | DNBSA | 0.03 | DBU | *1 | — | — |
| EX 53 | DTPA | 2.0 | Citric acid | 7.5 | 3.8 | LDPEDSA | 0.03 | DBU | *1 | — | — |
| EX 54 | DTPA | 2.0 | Citric acid | 7.5 | 3.8 | Lauryl | 0.03 | DBN | *1 | — | — |
| | | | | | | phosphoric acid | | | | | |
| EX 55 | DTPA | 2.0 | — | — | — | DBSA | 0.03 | DBU | *1 | — | — |
| EX 56 | DTPA | 2.0 | — | — | — | DNBSA | 0.03 | DBU | *1 | — | — |
| EX 57 | DTPA | 2.0 | — | — | — | LDPEDSA | 0.03 | DBU | *1 | — | — |
| EX 58 | DTPA | 2.0 | — | — | — | Lauryl | 0.03 | DBN | *1 | — | — |
| | | | | | | phosphoric acid | | | | | |
| EX 59 | DTPA | 2.0 | — | — | — | LDPEDSA | 0.03 | — | — | — | — |
| EX 60 | DTPA | 2.0 | — | — | — | LDPEDSA | 0.03 | — | — | — | — |

EX: Example

TABLE 5
Composition of cleaning liquid

| | | | | | | | | | | | Defect suppression | | |
|---|---|---|---|---|---|---|---|---|---|---|---|---|---|
| | | | | | | | | Defect suppression | | | performance (after | | |
| | Component B | | pH | | | Metal | pH | performance | | | storage test) | | |
| Table 2-2 | Anticorrosive | | adjuster | | | content | change | Object of Polishing | | | Object of Polishing | | |
| (continuation) | Type | Amount (%) | Type | Amount (%) | pH | (ppb) | evaluation | Cu | W | Co | Cu | W | Co |
| EX 31 | — | — | NH3 | *1 | 8.0 | <10 | A | B | B | B | C1 | C1 | C1 |
| EX 32 | — | — | Choline | *1 | 8.0 | <10 | A | B | B | B | B | B | B |
| EX 33 | — | — | — | — | 10.5 | <10 | A | A | A | A | B | B | B |
| EX 34 | — | — | AMP | 6.0 | 10.0 | <10 | A | A | A | A | A | B | A |
| EX 35 | — | — | AMP | 12.0 | 10.0 | <10 | A | A | A | A | A | A | A |
| EX 36 | — | — | — | — | 9.0 | <10 | A | A | A | A | B | B | B |
| EX 37 | — | — | — | — | 10.0 | <10 | A | A | A | A | B | B | B |
| EX 38 | — | — | — | — | 8.0 | <10 | A | A | A | A | B | B | B |
| EX 39 | — | — | — | — | 9.0 | <10 | A | A | A | A | B | B | B |
| EX 40 | — | — | — | — | 10.0 | <10 | A | A | A | A | B | B | B |
| EX 41 | — | — | — | — | 10.5 | <10 | A | A | A | A | B | B | B |
| EX 42 | — | — | — | — | 8.0 | <10 | A | A | A | A | B | B | B |
| EX 43 | — | — | TBAH | *1 | 9.0 | <10 | A | A | A | A | A | A | A |
| EX 44 | — | — | — | — | 9.0 | <10 | A | A | A | A | B | B | B |
| EX 45 | — | — | — | — | 10.0 | <10 | A | A | A | A | B | B | B |
| EX 46 | — | — | — | — | 9.0 | <10 | A | A | A | A | B | B | B |
| EX 47 | — | — | — | — | 10.0 | <10 | A | A | A | A | B | B | B |
| EX 48 | — | — | AMP | 6.0 | 10.5 | <10 | A | A | A | A | A | A | A |
| EX 49 | — | — | AMP | 6.0 | 10.5 | <10 | A | A | A | A | A | A | A |
| EX 50 | — | — | AMP | 6.0 | 10.5 | <10 | A | A | A | A | A | B | A |
| EX 51 | — | — | — | — | 8.0 | <10 | A | A | A | A | B | B | B |
| EX 52 | — | — | — | — | 8.0 | <10 | A | A | A | A | B | B | B |
| EX 53 | — | — | — | — | 8.0 | <10 | A | A | A | A | B | B | B |
| EX 54 | — | — | — | — | 10.5 | <10 | A | A | A | A | B | B | B |
| EX 55 | — | — | — | — | 8.0 | <10 | A | A | A | A | B | B | B |
| EX 56 | — | — | — | — | 8.0 | <10 | A | A | A | A | B | B | B |
| EX 57 | — | — | — | — | 8.0 | <10 | A | A | A | A | B | B | B |
| EX 58 | — | — | — | — | 10.5 | <10 | A | A | A | A | B | B | B |
| EX 59 | — | — | AMP | *1 | 8.0 | <10 | A | A | A | A | A | A | A |
| EX 60 | — | — | MEA | *1 | 8.0 | <10 | A | A | A | A | A | A | A |

EX: Example

TABLE 6
Composition of cleaning liquid

| | | | | | | Component B | | | | | |
|---|---|---|---|---|---|---|---|---|---|---|---|
| | Chelating agent | | | | | Surfactant | | Anticorrosive | | | |
| Table 2-3 | Type | Amount | Type | Amount | Ratio | Type | Amount | Type | Amount | Type | Amount |
| | | (%) | | (%) | | | (%) | | (%) | | (%) |
| EX 61 | DTPA | 2.0 | — | — | — | LDPEDSA | 0.03 | — | — | — | — |
| EX 62 | HEDP | 0.04 | — | — | — | Lauryl | 0.03 | DBU | *1 | — | — |
| | | | | | | phosphoric | | | | | |
| | | | | | | acid | | | | | |
| EX 63 | HEDP | 0.04 | — | — | — | Lauryl | 0.03 | DBU | *1 | — | — |
| | | | | | | phosphoric | | | | | |
| | | | | | | acid | | | | | |
| EX 64 | HEDP | 1.0 | — | — | — | Lauryl | 0.03 | DBU | *1 | — | — |
| | | | | | | phosphoric | | | | | |
| | | | | | | acid | | | | | |
| EX 65 | HEDP | 1.0 | — | — | — | Lauryl | 0.03 | DBU | *1 | — | — |
| | | | | | | phosphoric | | | | | |
| | | | | | | acid | | | | | |
| EX 66 | HEDP | 1.0 | — | — | — | Lauryl | 0.03 | — | — | — | — |
| | | | | | | phosphoric | | | | | |
| | | | | | | acid | | | | | |
| EX 67 | HEDP | 1.0 | — | — | — | Lauryl | 0.03 | — | — | — | — |
| | | | | | | phosphoric | | | | | |
| | | | | | | acid | | | | | |
| EX 68 | HEDP | 1.0 | — | — | — | Lauryl | 0.03 | — | — | — | — |
| | | | | | | phosphoric | | | | | |
| | | | | | | acid | | | | | |
| EX 69 | Citric acid | 7.5 | HEDP | 0.04 | 187.5 | DBSA | 0.03 | DBU | *1 | — | — |
| EX 70 | HEDP | 0.04 | — | — | — | — | — | 5- | 0.2 | DBN | *1 |
| | | | | | | | | Aminotetrazole | | | |
| EX 71 | HEDP | 0.04 | — | — | — | — | — | 1H-Tetrazole | 0.2 | DBU | *1 |
| EX 72 | Citric acid | 7.5 | HEDP | 0.04 | 187.5 | — | — | 5- | 0.2 | DBU | *1 |
| | | | | | | | | Aminotetrazole | | | |
| EX 73 | Citric acid | 7.5 | HEDP | 0.04 | 187.5 | — | — | 1H-Tetrazole | 0.2 | DBU | *1 |
| EX 74 | Citric acid | 7.5 | HEDP | 0.04 | 187.5 | — | — | 5- | 0.2 | DBU | *1 |
| | | | | | | | | Aminotetrazole | | | |
| EX 75 | Citric acid | 0.008 | HEDP | 0.04 | 5.0 | Lauryl | 0.03 | DBU | *1 | — | — |
| | | | | | | phosphoric | | | | | |
| | | | | | | acid | | | | | |
| EX 76 | Citric acid | 0.05 | HEDP | 0.04 | 1.3 | Lauryl | 0.03 | DBU | *1 | — | — |
| | | | | | | phosphoric | | | | | |
| | | | | | | acid | | | | | |
| EX 77 | Citric acid | 10.0 | HEDP | 0.04 | 250.0 | Lauryl | 0.03 | DBU | *1 | — | — |
| | | | | | | phosphoric | | | | | |
| | | | | | | acid | | | | | |
| EX 78 | Citric acid | 30.0 | HEDP | 0.38 | 78.9 | Lauryl | 0.03 | DBU | *1 | — | — |
| | | | | | | phosphoric | | | | | |
| | | | | | | acid | | | | | |
| EX 79 | Citric acid | 7.5 | HEDP | 0.04 | 187.5 | Lauryl | 0.003 | DBU | *1 | — | — |
| | | | | | | phosphoric | | | | | |
| | | | | | | acid | | | | | |
| EX 80 | Citric acid | 7.5 | HEDP | 0.04 | 187.5 | Lauryl | 0.3 | DBU | *1 | — | — |
| | | | | | | phosphoric | | | | | |
| | | | | | | acid | | | | | |
| EX 81 | Citric acid | 7.5 | HEDP | 0.04 | 187.5 | Lauryl | 3.0 | DBU | *1 | — | — |
| | | | | | | phosphoric | | | | | |
| | | | | | | acid | | | | | |
| EX 82 | Citric acid | 7.5 | HEDP | 0.04 | 187.5 | Lauryl | 0.03 | DBU | *1 | — | — |
| | | | | | | phosphoric | | | | | |
| | | | | | | acid | | | | | |
| EX 83 | Citric acid | 7.5 | HEDP | 0.04 | 187.5 | Lauryl | 0.03 | DBU | *1 | — | — |
| | | | | | | phosphoric | | | | | |
| | | | | | | acid | | | | | |
| EX 84 | Citric acid | 7.5 | HEDP | 0.04 | 187.5 | Lauryl | 0.03 | DBN | *1 | DEHA | 5.0 |
| | | | | | | phosphoric | | | | | |
| | | | | | | acid | | | | | |
| EX 85 | Citric acid | 7.5 | HEDP | 0.04 | 187.5 | Lauryl | 0.03 | DBU | *1 | DEHA | 0.5 |
| | | | | | | phosphoric | | | | | |
| | | | | | | acid | | | | | |
| EX 86 | Tartaric | 0.03 | Arginine | 0.1 | 3.3 | — | — | 1,2,4-Triazole | 0.67 | 2- | 0.67 |
| | acid | | | | | | | | | Aminopyrimidine | |
| EX 87 | DTPA | 0.1 | Gly | 0.06 | 1.7 | LDPEDSA | 0.03 | — | — | — | — |
| EX 88 | DTPA | 0.1 | ALA | 0.1 | 1.0 | LDPEDSA | 0.03 | — | — | — | — |
| EX 89 | DTPA | 0.5 | Gly | 0.06 | 8.3 | LDPEDSA | 0.03 | DEHA | 4.5 | — | — |
| EX 90 | DTPA | 0.5 | Gly | 0.06 | 8.3 | LDPEDSA | 0.03 | Ascorbic acid | 1.0 | — | — |

EX: Example

TABLE 7
Composition of cleaning liquid

| | | | | | | | | | | | Defect suppression | | |
|---|---|---|---|---|---|---|---|---|---|---|---|---|---|
| | | | | | | | | Defect suppression | | | performance (after | | |
| | Component B | | pH | | | Metal | pH | performance | | | storage test) | | |
| Table 2-3 | Anticorrosive | | adjuster | | | content | change | Object of Polishing | | | Object of Polishing | | |
| (continuation) | Type | Amount (%) | Type | Amount (%) | pH | (ppb) | evaluation | Cu | W | Co | Cu | W | Co |
| EX 61 | — | — | DEA | *1 | 8.0 | <10 | A | A | A | A | A | A | A |
| EX 62 | — | — | — | — | 8.0 | <10 | A | A | A | A | B | B | B |
| EX 63 | — | — | — | — | 10.5 | <10 | A | A | A | A | B | B | B |
| EX 64 | — | — | — | — | 8.0 | <10 | A | A | A | A | B | B | B |
| EX 65 | — | — | — | — | 10.5 | <10 | A | A | A | A | B | B | B |
| EX 66 | — | — | AMP | *1 | 10.5 | <10 | A | A | A | A | A | A | A |
| EX 67 | — | — | MEA | *1 | 10.5 | <10 | A | A | A | A | A | A | A |
| EX 68 | — | — | DEA | *1 | 10.5 | <10 | A | A | A | A | A | A | A |
| EX 69 | — | — | — | — | 8.0 | <10 | A | A | A | A | B | B | B |
| EX 70 | — | — | — | — | 10.5 | <10 | A | A | A | A | B | B | B |
| EX 71 | — | — | — | — | 10.5 | <10 | A | A | A | A | B | B | B |
| EX 72 | — | — | — | — | 8.0 | <10 | A | A | A | A | B | B | B |
| EX 73 | — | — | — | — | 8.0 | <10 | A | A | A | A | B | B | B |
| EX 74 | — | — | — | — | 8.0 | <10 | A | A | A | A | B | B | B |
| EX 75 | — | — | — | — | 8.0 | <10 | A | A | A | A | B | B | B |
| EX 76 | — | — | — | — | 8.0 | <10 | A | A | A | A | B | B | B |
| EX 77 | — | — | — | — | 8.0 | <10 | A | A | A | A | B | B | B |
| EX 78 | — | — | — | — | 8.0 | <10 | A | A | A | A | B | B | B |
| EX 79 | — | — | — | — | 8.0 | <10 | A | A | A | A | B | B | B |
| EX 80 | — | — | — | — | 8.0 | <10 | A | A | A | A | B | B | B |
| EX 81 | — | — | — | — | 8.0 | <10 | A | A | A | A | B | B | B |
| EX 82 | — | — | — | — | 8.0 | <0.1 | A | A | A | A | B | B | B |
| EX 83 | — | — | — | — | 8.0 | >100000 | A | A | A | A | B | B | B |
| EX 84 | — | — | — | — | 8.0 | <10 | A | A | A | A | B | B | B |
| EX 85 | — | — | — | — | 8.0 | <10 | A | A | A | A | B | B | B |
| EX 86 | — | — | Tris | *1 | 8.9 | <10 | A | A | A | A | A | A | A |
| EX 87 | — | — | AMP | 6.0 | 11.0 | <10 | A | A | A | A | A | A | A |
| EX 88 | — | — | AMP | 6.0 | 11.0 | <10 | A | A | A | A | A | A | A |
| EX 89 | — | — | AMP | 6.0 | 11.0 | <10 | A | A | A | A | A | B | A |
| EX 90 | — | — | AMP | 6.0 | 11.0 | <10 | A | A | A | A | A | B | A |

EX: Example

TABLE 8
Composition of cleaning liquid

| | | | | | | Component B | | | | | |
|---|---|---|---|---|---|---|---|---|---|---|---|
| | Chelating agent | | | | | Surfactant | | Anticorrosive | | | |
| Table 2-4 | Type | Amount | Type | Amount | Ratio | Type | Amount | Type | Amount | Type | Amount |
| | | (%) | | (%) | | | (%) | | (%) | | (%) |
| EX 91 | DTPA | 0.5 | Gly | 0.06 | 8.3 | LDPEDSA | 0.03 | Gallic acid | 1.0 | — | — |
| EX 92 | DTPA | 0.5 | ALA | 0.1 | 5.0 | LDPEDSA | 0.03 | DEHA | 4.5 | — | — |
| EX 93 | DTPA | 0.5 | — | — | — | LDPEDSA | 0.03 | — | — | — | — |
| | | | | | | POED | 0.01 | | | | |
| EX 94 | EDTA | 0.5 | — | — | — | LDPEDSA | 0.03 | — | — | — | |
| | | | | | | POED | 0.01 | | | | |
| EX 95 | DTPA | 0.1 | Gly | 0.06 | 1.7 | LDPEDSA | 0.03 | — | — | — | — |
| EX 96 | DTPA | 0.1 | Gly | 0.06 | 1.7 | LDPEDSA | 0.03 | — | — | — | — |
| EX 97 | DTPA | 0.1 | Gly | 0.06 | 1.7 | LDPEDSA | 0.03 | — | — | — | — |
| EX 98 | DTPA | 0.1 | Gly | 0.06 | 1.7 | LDPEDSA | 0.03 | — | — | — | — |
| EX 99 | DTPA | 0.1 | Gly | 0.06 | 1.7 | LDPEDSA | 0.03 | BAP | 6.0 | — | — |
| EX 100 | DTPA | 0.1 | Gly | 0.06 | 1.7 | LDPEDSA | 0.03 | — | — | — | — |
| EX 101 | DTPA | 0.1 | Gly | 0.06 | 1.7 | LDPEDSA | 0.03 | — | — | — | — |
| EX 102 | DTPA | 0.1 | Gly | 0.06 | 1.7 | LDPEDSA | 0.03 | REP | 6.0 | — | — |
| EX 103 | HEDP | 0.04 | — | — | — | POE Lauryl | 0.03 | DEHA | 4.5 | — | — |
| | | | | | | phosphoric | | | | | |
| | | | | | | acid | | | | | |
| CE 1 | Citric acid | 7.5 | HEDP | 0.04 | 187.5 | Lauryl | 0.03 | DBU | *1 | — | — |
| | | | | | | phosphoric | | | | | |
| | | | | | | acid | | | | | |
| CE 2 | Citric acid | 7.5 | HEDP | 0.04 | 187.5 | Lauryl | 0.03 | DBU | *1 | — | — |
| | | | | | | phosphoric | | | | | |
| | | | | | | acid | | | | | |
| CE 3 | Citric acid | 7.5 | HEDP | 0.04 | 187.5 | Lauryl | 0.03 | DBU | *1 | — | — |
| | | | | | | phosphoric | | | | | |
| | | | | | | acid | | | | | |
| CE 4 | Citric acid | 0.5 | — | — | — | DBSA | 0.5 | 1, 3- | 0.5 | — | — |
| | | | | | | | | Diaminopropane | | | |

EX: Example
CE: Comparative Example

TABLE 9
Composition of cleaning liquid

| | | | | | | | | | | | Defect suppression | | |
|---|---|---|---|---|---|---|---|---|---|---|---|---|---|
| | | | | | | | | Defect suppression | | | performance (after | | |
| | Component B | | pH | | | Metal | pH | performance | | | storage test) | | |
| Table 2-4 | Anticorrosive | | adjuster | | | content | change | Object of Polishing | | | Object of Polishing | | |
| (continuation) | Type | Amount (%) | Type | Amount (%) | pH | (ppb) | evaluation | Cu | W | Co | Cu | W | Co |
| EX 91 | — | — | AMP | 6.0 | 11.0 | <10 | A | A | A | A | A | B | A |
| EX 92 | — | — | AMP | 6.0 | 11.0 | <10 | A | A | A | A | A | B | A |
| EX 93 | — | — | AMP | 6.0 | 11.0 | <10 | A | A | A | A | A | A | A |
| EX 94 | — | — | AMP | 6.0 | 11.0 | <10 | A | A | A | A | A | A | A |
| EX 95 | — | — | Tris | 6.0 | 9.0 | <10 | A | A | A | A | A | A | A |
| EX 96 | — | — | MEA | 6.0 | 10.0 | <10 | A | A | A | A | A | A | A |
| EX 97 | — | — | DEA | 6.0 | 10.0 | <10 | A | A | A | A | A | A | A |
| EX 98 | — | — | AH212 | 6.0 | 10.0 | <10 | A | A | A | A | A | A | A |
| EX 99 | — | — | — | — | 11.0 | <10 | A | A | A | A | A | A | A |
| EX 100 | — | — | AEE | 6.0 | 11.0 | <10 | A | A | A | A | A | A | A |
| EX 101 | — | — | AEM | 6.0 | 11.0 | <10 | A | A | A | A | A | A | A |
| EX 102 | — | — | — | — | 11.0 | <10 | A | A | A | A | A | A | A |
| EX 103 | — | — | AMP | 6.0 | 10.0 | <10 | A | A | A | A | A | B | A |
| CE 1 | — | — | — | — | 9.0 | <10 | C | C | C | C | C1 | C1 | C1 |
| CE 2 | — | — | — | — | 10.0 | <10 | D | D | D | D | D | D | D |
| CE 3 | — | — | — | — | 13.0 | <10 | D | D | D | D | D | D | D |
| CE 4 | — | — | AH212 | *1 | 12.0 | <10 | D | D | D | D | D | D | D |

EX: Example
CE: Comparative Example

As evident from the acidity constants (pKa) of the chelating agents shown in Table 1 and the pH values of the cleaning liquids shown in Tables 2-1 to 2-4, all of the cleaning liquids of Examples 1 to 103 satisfy the relationship of Formula (A) above between the pKa of the chelating agent and the pH of the cleaning liquid.

As evident from Table 1 and Tables 2-1 to 2-4, it was confirmed that the cleaning liquid of the present invention that contains the chelating agent and satisfies Formula (A) above has excellent performance in suppressing a change in the pH caused by dilution.

It was confirmed that when the cleaning liquid contains the anticorrosive, the defect suppression performance for the copper-containing film and the tungsten-containing film is excellent (see the comparison between the results of Examples 1 to 3).

It was confirmed that when the cleaning liquid contains the surfactant, the defect suppression performance for the copper-containing film is excellent (see the comparison between the results of Examples 2, 3, 31 and 32).

It was confirmed that when the cleaning liquid contains both the surfactant and the anticorrosive, the defect suppression performance for the cobalt-containing film is more excellent (see the comparison between the results of Examples 1, 2, 30 and 31).

It was confirmed that when the cleaning liquid contains the alkanolamine, the defect suppression performance for the copper-containing film and the tungsten-containing film is excellent (see the comparison between the results of Examples 2 and 18).

It was confirmed that when the cleaning liquid contains the basic organic compound, the storage stability of the cleaning liquid is excellent (see the comparison between the results of Examples 2, 3, 14 and 18).

It was confirmed that when the cleaning liquid contains all of the chelating agent, the surfactant and the basic organic compound, the defect suppression performance for the copper-containing film and the cobalt-containing film is excellent (see the comparison between the results of Examples 18 to 22, 30 to 32, 48 to 50, 59 to 61, 66 to 68, 87 to 98, 100 and 101).

### [Evaluation of Corrosion Suppression Performance]

Cleaning liquids of Examples 111 to 114 with the compositions shown in Table 3 were manufactured according to the manufacturing method of Example 1. In each cleaning liquid, the remainder other than those components shown in Table 3 was water.

Two milliliters of the cleaning liquid of each of Examples was taken and diluted 100 times in volume ratio with ultrapure water to prepare a sample of the diluted cleaning liquid (200 mL).

A wafer (diameter: 12 inches) having on its surface a metal film made of copper, cobalt or tungsten was cut to prepare a wafer coupon of 2 cm square. The thickness of each metal film was set to 200 nm. The wafer was immersed in the sample of the diluted cleaning liquid manufactured by the foregoing method and subjected to a 30-minute immersion treatment at a stirring rotational speed of 250 rpm and at room temperature. For each metal film, the film thicknesses before and after the immersion treatment were calculated, and the corrosion rate per unit time was calculated from the calculation results. Each cleaning liquid was evaluated for the corrosion suppression performance according to the following evaluation criteria. The results are shown in Table 3.

Note that a lower corrosion rate indicates better corrosion suppression performance of the cleaning liquid.

“A”: A corrosion rate of not more than 1 Å/min

“B”: A corrosion rate of more than 1 Å/min and less than 3 Å/min

“C”: A corrosion rate of not less than 3 Å/min

TABLE 10
Composition of cleaning liquid

| | | | | | | | | | | | Corrosion | | |
|---|---|---|---|---|---|---|---|---|---|---|---|---|---|
| | | | | | | | | | | | suppression | | |
| | | | Component B | | | | pH | | | Metal | performance | | |
| | Chelating agent | | Surfactant | | Anticorrosive | | adjuster | | | content | Object of polishing | | |
| Table 3 | Type | Amount (%) | Type | Amount (%) | Type | Amount (%) | Type | Amount (%) | pH | (ppb) | Cu | W | Co |
| EX 111 | HEDP | 0.04 | — | — | DEHA | 4.5 | AMP | 12.0 | 10.5 | <10 | A | A | B |
| EX 112 | HEDP | 0.04 | — | — | — | — | AMP | 12.0 | 10.0 | <10 | B | B | B |
| EX 113 | DTPA | 0.1 | LDPEDSA | 0.03 | — | — | AMP | *6 | 10.5 | <10 | B | B | B |
| EX 114 | DTPA | 0.1 | LDPEDSA | 0.03 | DENA | 4.5 | AMP | *6 | 10.5 | <10 | A | A | A |

EX: Example

It was confirmed from the results shown in Table 3 that when the cleaning liquid contains the hydroxylamine compound as the anticorrosive, the corrosion suppression performance is excellent (see the comparison between the results of Examples 111 to 114).

It was also confirmed that when the cleaning liquid containing the hydroxylamine compound contains the carboxylic acid-based chelating agent, the corrosion suppression performance is excellent compared to that containing the phosphonic acid-based chelating agent (see the comparison between the results of Examples 111 and 114).

It was also confirmed that when the cleaning liquid containing the hydroxylamine compound contains the surfactant, the corrosion suppression performance is excellent compared to that free from the surfactant (see the comparison between the results of Examples 111 and 114).

### [Evaluation of Temperature of Cleaning Liquid]

The composition of Example 49 was evaluated for the defect suppression performance and the storage stability according to the evaluation method for the defect suppression performance and the evaluation test method for the storage stability as described above except that the temperature of the sample of the diluted cleaning liquid at the time of cleaning was set to 30° C. to 50° C. As a result, favorable effects similar to those when the temperature was room temperature (23° C.) were obtained.

### [Evaluation of Concentration of Cleaning Liquid]

A sample of a cleaning liquid was evaluated for a change in the pH caused by dilution, the defect suppression performance and the storage stability according to the evaluation method for a change in the pH caused by dilution, the evaluation method for the defect suppression performance, and the evaluation test method for the storage stability as described above except that in place of the cleaning liquid of Example 49, use was made of the cleaning liquid in which the contents of the components (DTPA, LDPEDSA and AMP) other than water were 10 times their contents of the cleaning liquid of Example 49 and that the cleaning liquid was diluted 1000 times in volume ratio with ultrapure water to thereby prepare the sample of the diluted cleaning liquid. As a result, favorable effects similar to those of Example 49 were obtained.

What is claimed is:

1. A cleaning liquid for semiconductor substrates, the cleaning liquid containing a chelating agent,
wherein an acidity constant (pKa) of the chelating agent and a pH of the cleaning liquid satisfy a condition defined by Formula (A):
pKa−1<pH<pKa+1 (A)

2. The cleaning liquid according to claim 1,
wherein the chelating agent has at least one coordination group selected from a carboxy group and a phosphonic acid group.

3. The cleaning liquid according to claim 1,
wherein the chelating agent includes at least one selected from diethylenetriaminepentaacetic acid, ethylenediamine tetraacetic acid, iminodiacetic acid, glycine, β-alanine, arginine, citric acid, tartaric acid, 1-hydroxyethylidene-1,1′-diphosphonic acid, and ethylenediamine tetra(methylenephosphonic acid).

4. The cleaning liquid according to claim 1,
wherein the cleaning liquid contains two or more chelating agents included in the chelating agent.

5. The cleaning liquid according to claim 4,
wherein a ratio of a content of one chelating agent of the two or more chelating agents to a content of another chelating agent thereof is 1 to 5000 in mass ratio.

6. The cleaning liquid according to claim 1,
wherein a content of the chelating agent is 0.01 to 30 mass % based on a total mass of the cleaning liquid.

7. The cleaning liquid according to claim 1,
wherein the cleaning liquid further contains at least one component selected from a surfactant and an anticorrosive.

8. The cleaning liquid according to claim 7,
wherein the anticorrosive includes at least one selected from the group consisting of a heterocyclic compound, a hydroxylamine compound, an ascorbic acid compound, and a catechol compound.

9. The cleaning liquid according to claim 8,
wherein the heterocyclic compound includes at least one selected from the group consisting of an azole compound, a pyridine compound, a pyrazine compound, a pyrimidine compound, a piperazine compound, and a cyclic amidine compound.

10. The cleaning liquid according to claim 1,
wherein the cleaning liquid further contains a surfactant and a basic organic compound.

11. The cleaning liquid according to claim 7,
wherein the surfactant includes an anionic surfactant.

12. The cleaning liquid according to claim 11,
wherein the anionic surfactant includes at least one selected from the group consisting of a phosphoric acid ester-based surfactant, a phosphonic acid-based surfactant, a sulfonic acid-based surfactant, and a carboxylic acid-based surfactant.

13. The cleaning liquid according to claim 11,
wherein the chelating agent includes a carboxylic acid-based chelating agent having a carboxy group or a phosphonic acid-based chelating agent having a phosphonic acid group, and
the anionic surfactant includes at least one selected from the group consisting of a phosphoric acid ester-based surfactant, a phosphonic acid-based surfactant, a sulfonic acid-based surfactant, and a carboxylic acid-based surfactant.

14. The cleaning liquid according to claim 7,
wherein the surfactant includes a nonionic surfactant.

15. The cleaning liquid according to claim 1,
wherein the cleaning liquid further contains a pH adjuster.

16. The cleaning liquid according to claim 1,
wherein the cleaning liquid has a pH of 7.5 to 12.0 at 25° C.

17. The cleaning liquid according to claim 1, further containing water.

18. The cleaning liquid according to claim 1,
wherein a content of metal in the cleaning liquid is not more than 100 ppb by mass based on a total mass of the cleaning liquid.

19. The cleaning liquid according to claim 1,
wherein a content of particles with a particle size of 0.4 μm or more in the cleaning liquid is not more than 1000 particles per milliliter of the cleaning liquid.

20. The cleaning liquid according to claim 1,
wherein the cleaning liquid is used in cleaning of semiconductor substrates having undergone a chemical mechanical polishing process.
